(19) United States
(12) Patent Application Publication
(10) Pub. No.: US 2026/0052992 A1
(43) Pub. Date: Feb. 19, 2026

(54) HYBRID BONDING USING STRESS-RELIEF DUMMY PADS AND METHODS OF FORMING AND USING THE SAME

(71) Applicant: Taiwan Semiconductor Manufacturing Company Limited, Hsinchu (TW)

(72) Inventors: Jen-Yuan Chang, Hsinchu City (TW); Kuo-Lung Li, Taoyuan City (TW); Hong-Yang Lin, Hsinchu (TW); Jhih-Wei Chen, Hsinchu (TW); Li-Ho Chu, Hsinchu (TW); Chi-Yen Lin, Tainan City (TW)

(21) Appl. No.: 18/808,371

(22) Filed: Aug. 19, 2024

(51) Int. Cl. H01L 23/00; H01L 21/56; H01L 23/31; H01L 23/48; H01L 23/528; H01L 23/58; H01L 25/065

(52) U.S. Cl. CPC H01L 24/08; H01L 21/568; H01L 23/3121; H01L 23/585; H01L 24/03; H01L 24/80; H01L 23/481; H01L 23/5283; H01L 24/05; H01L 24/06; H01L 25/0657; H01L 2224/033; H01L 2224/03616; H01L 2224/05541; H01L 2224/0613; H01L 2224/06505; H01L 2224/08145; H01L 2224/80895; H01L 2224/80896; H01L 2924/3512

(57) ABSTRACT

A semiconductor structure may be provided by forming a first molding compound around a first semiconductor die such that a top surface of the first molding compound is coplanar with a top dielectric surface of the first semiconductor die; forming a combination of at least one bonding-level dielectric layer, first bonding pads, and dummy pads over the first semiconductor die and the first molding compound, wherein each of the bonding pads is formed directly on a respective conductive structure within the first semiconductor die; and attaching a second semiconductor die including second bonding pads therein to the first semiconductor die by performing a bonding process that bonds the second bonding pads to the first bonding pads by metal-to-metal bonding such that a first subset of the dummy pads has an areal overlap in a plan view with the second semiconductor die.

### BACKGROUND

Stress at a bonding interface between a mating pair of semiconductor dies may induce cracks in a gap fill material such as silicon dioxide. Such cracks tend to extend around the bonding interface, and adversely impact the reliability of a bonded assembly including the mating pair of semiconductor dies through various mechanisms. For example, ingress of moisture and contaminants may lead to corrosion of components and degradation of electrical properties. Additionally, the structural integrity of the bonded assembly may be compromised, resulting in mechanical failures that reduce the overall lifespan and/or performance of the semiconductor devices in the bonded assembly. The presence of such cracks may also lead to increased thermal resistance, adversely affecting the thermal management and operational stability of the bonded assembly.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for the clarity of discussion.

FIG. 1 is a top-down view of an exemplary structure including a carrier substrate with an array of first semiconductor dies thereupon according to an aspect of the present disclosure.

FIGS. 2A-2F are sequential vertical cross-sectional views of a unit area of the exemplary structure during formation of a reconstituted wafer including a two-dimensional array of composite dies having a first configuration and singulation into discrete composite dies according to an aspect of the present disclosure.

FIG. 3 is a see-through top-down view of a composite die having the first configuration according to an embodiment of the present disclosure.

FIGS. 4A-4E are sequential vertical cross-sectional views of a region of the first configuration of the exemplary structure around at least one bonding-level dielectric layer during formation of dummy pads and bonding pads according to an embodiment of the present disclosure.

FIGS. 5A-5E are sequential vertical cross-sectional views of a region of a second configuration of the exemplary structure around at least one bonding-level dielectric layer during formation of dummy pads and bonding pads according to an embodiment of the present disclosure.

FIG. 5F is a vertical cross-sectional view of a composite die having the second configuration according to an embodiment of the present disclosure.

FIGS. 6A-6E are sequential vertical cross-sectional views of a region of a third configuration of the exemplary structure around at least one bonding-level dielectric layer during formation of dummy pads and bonding pads according to an embodiment of the present disclosure.

FIG. 6F is a vertical cross-sectional view of a composite die having the third configuration according to an embodiment of the present disclosure.

FIGS. 7A-7E are sequential vertical cross-sectional views of a region of a fourth configuration of the exemplary structure around at least one bonding-level dielectric layer during the formation of dummy pads and bonding pads according to an embodiment of the present disclosure.

FIG. 7F is a vertical cross-sectional view of a composite die having the fourth configuration according to an embodiment of the present disclosure.

FIGS. 8A-8E are sequential vertical cross-sectional views of a region of a fifth configuration of the exemplary structure around at least one bonding-level dielectric layer during the formation of dummy pads and bonding pads according to an embodiment of the present disclosure.

FIG. 8F is a vertical cross-sectional view of a composite die having the fifth configuration according to an embodiment of the present disclosure.

FIGS. 9A-9D are sequential vertical cross-sectional views of a region of a sixth configuration of the exemplary structure around at least one bonding-level dielectric layer during the formation of dummy pads and bonding pads according to an embodiment of the present disclosure.

FIG. 9E is a vertical cross-sectional view of a composite die having the sixth configuration according to an embodiment of the present disclosure.

FIGS. 10A-10E are sequential vertical cross-sectional views of a region of a seventh configuration of the exemplary structure around at least one bonding-level dielectric layer during the formation of dummy pads and bonding pads according to an embodiment of the present disclosure.

FIG. 10F is a vertical cross-sectional view of a composite die having the seventh configuration according to an embodiment of the present disclosure.

FIGS. 11A-11C are sequential vertical cross-sectional views of a region of an eighth configuration of the exemplary structure around at least one bonding-level dielectric layer during the formation of dummy pads and bonding pads according to an embodiment of the present disclosure.

FIG. 11D is a vertical cross-sectional view of a composite die having the eighth configuration according to an embodiment of the present disclosure.

FIGS. 12A-12G are sequential vertical cross-sectional views of a region of a ninth configuration of the exemplary structure around at least one bonding-level dielectric layer during the formation of dummy pads and bonding pads according to an embodiment of the present disclosure.

FIG. 12H is a vertical cross-sectional view of a composite die having the ninth configuration according to an embodiment of the present disclosure.

FIGS. 13A-13G are sequential vertical cross-sectional views of a region of a tenth configuration of the exemplary structure around at least one bonding-level dielectric layer during the formation of dummy pads and bonding pads according to an embodiment of the present disclosure.

FIG. 13H is a vertical cross-sectional view of a composite die having the tenth configuration according to an embodiment of the present disclosure.

FIGS. 14A-14F are sequential vertical cross-sectional views of a region of an eleventh configuration of the exemplary structure around at least one bonding-level dielectric layer during the formation of dummy pads and bonding pads according to an embodiment of the present disclosure.

FIG. 14G is a vertical cross-sectional view of a composite die having the eleventh configuration according to an embodiment of the present disclosure.

FIGS. 15A-15F are sequential vertical cross-sectional views of a region of a twelfth configuration of the exemplary structure around at least one bonding-level dielectric layer during the formation of dummy pads and bonding pads according to an embodiment of the present disclosure.

FIG. 15G is a vertical cross-sectional view of a composite die having the twelfth configuration according to an embodiment of the present disclosure.

FIGS. 16A-16E are sequential vertical cross-sectional views of a region of a thirteenth configuration of the exemplary structure around at least one bonding-level dielectric layer during the formation of dummy pads and bonding pads according to an embodiment of the present disclosure.

FIG. 16F is a vertical cross-sectional view of a composite die having the thirteenth configuration according to an embodiment of the present disclosure.

FIGS. 17A-17E are sequential vertical cross-sectional views of a region of a fourteenth configuration of the exemplary structure around at least one bonding-level dielectric layer during the formation of dummy pads and bonding pads according to an embodiment of the present disclosure.

FIG. 17F is a vertical cross-sectional view of a composite die having the fourteenth configuration according to an embodiment of the present disclosure.

FIGS. 18A-18E are sequential vertical cross-sectional views of a region of a fifteenth configuration of the exemplary structure around at least one bonding-level dielectric layer during the formation of dummy pads and bonding pads according to an embodiment of the present disclosure.

FIG. 18F is a vertical cross-sectional view of a composite die having the fifteenth configuration according to an embodiment of the present disclosure.

FIGS. 19A-19D are sequential vertical cross-sectional views of a region of a sixteenth configuration of the exemplary structure around at least one bonding-level dielectric layer during the formation of dummy pads and bonding pads according to an embodiment of the present disclosure.

FIG. 19E is a vertical cross-sectional view of a composite die having the sixteenth configuration according to an embodiment of the present disclosure.

FIGS. 20A-20E are sequential vertical cross-sectional views of a region of a seventeenth configuration of the exemplary structure around at least one bonding-level dielectric layer during the formation of dummy pads and bonding pads according to an embodiment of the present disclosure.

FIGS. 21A-21C are vertical cross-sectional views of various embodiments of a composite die having the seventeenth configuration according to an embodiment of the present disclosure.

FIGS. 22A-22E are sequential vertical cross-sectional views of a region of an eighteenth configuration of the exemplary structure around at least one bonding-level dielectric layer during the formation of dummy pads and bonding pads according to an embodiment of the present disclosure.

FIG. 22F is a vertical cross-sectional view of a composite die having the eighteenth configuration according to an embodiment of the present disclosure.

FIGS. 23A-23E are sequential vertical cross-sectional views of a region of a nineteenth configuration of the exemplary structure around at least one bonding-level dielectric layer during the formation of dummy pads and bonding pads according to an embodiment of the present disclosure.

FIG. 23F is a vertical cross-sectional view of a composite die having the nineteenth configuration according to an embodiment of the present disclosure.

FIG. 24 is a vertical cross-sectional view of a composite die having a twentieth configuration according to an embodiment of the present disclosure.

FIGS. 25A-25E are see-through top-down views of a composite die having various configurations according to an embodiment of the present disclosure.

FIG. 26 is a first flowchart illustrating steps for forming a semiconductor structure according to an embodiment of the present disclosure.

FIG. 27 is a second flowchart illustrating steps for forming a semiconductor structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Embodiments of the present disclosure are directed to methods of bonding semiconductor dies that use dummy pads and bonding pads. The dummy pads and bonding pads may be used to provide metal-to-metal bonding or hybrid bonding between a bonded pair of semiconductor dies, while reducing crack defects and improving the bonding yield. The dummy pads may be formed over a first semiconductor die under and around a peripheral region of a second semiconductor die to be subsequently attached. The dummy pads mitigate stress-related issues and prevent the formation of cracks in a gap fill material that is to be applied around the second semiconductor die. The various aspect of the present disclosure are now described with reference to accompanying drawings.

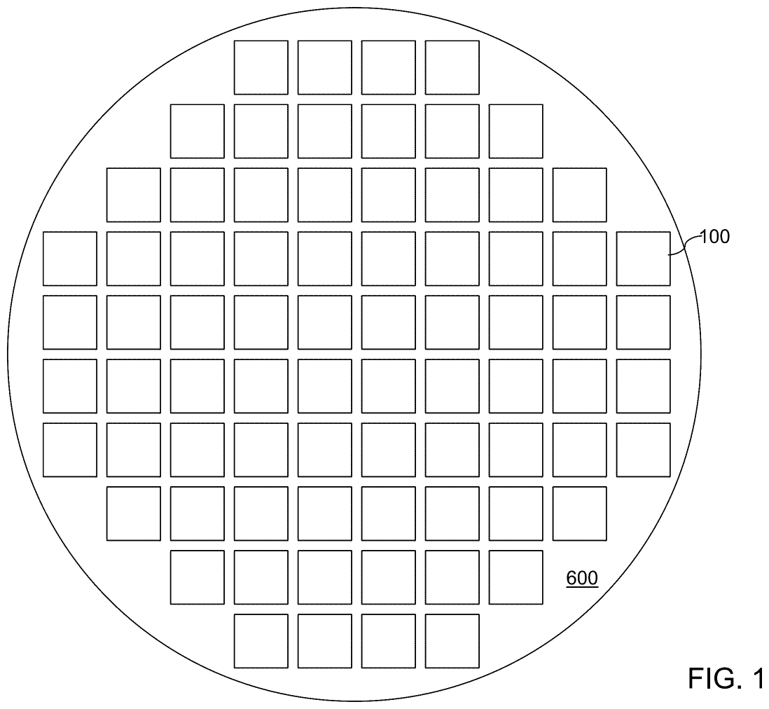

Referring to FIG. 1, a top-down view of an exemplary structure is shown. The exemplary structure includes a carrier substrate 600 with an array of first semiconductor dies 100 thereupon. The carrier substrate 600 may be any type of carrier substrate that is suitable for carrying an array of semiconductor dies thereupon. For example, the carrier substrate 600 may be a glass substrate, a semiconductor substrate, or a conductive substrate. As shown in FIG. 1, the carrier substrate 600 may have a circular shape. In other embodiments (not shown), the carrier substrate may have a rectangular shape, or any other shape that is suitable for carrying an array of semiconductor dies thereupon. The first semiconductor dies 100 may be any type of semiconductor dies known in the art. For example, the first semiconductor dies 100 may comprise logic dies including at least one central processing unit (CPU), at least one graphic processing unit (GPU), at least one neural processing unit (NPU), at least one memory array, and/or any other type of semiconductor devices known in the art. The array of the first semiconductor dies 100 may be attached to the carrier substrate 600 using an adhesive layer. The array of the first semiconductor dies 100 may be arranged as a periodic two-dimensional array. The area that form a minimum unit of repetition within the periodic two-dimensional array is herein referred to as unit area.

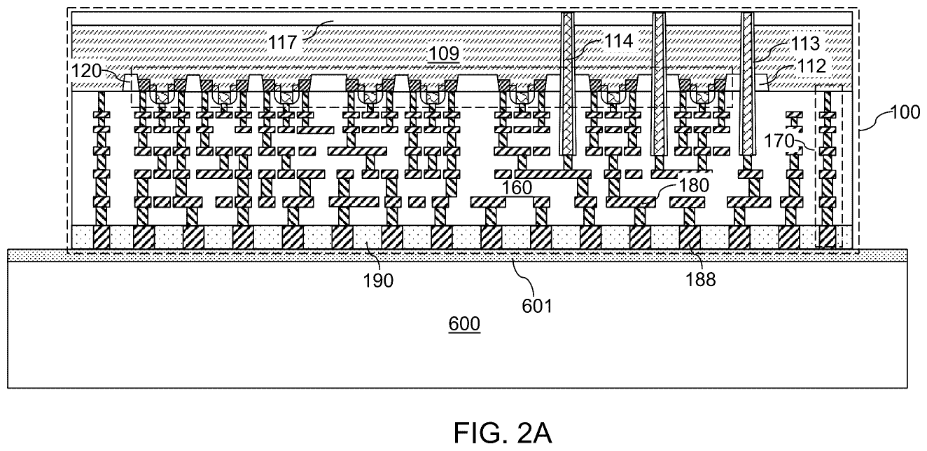

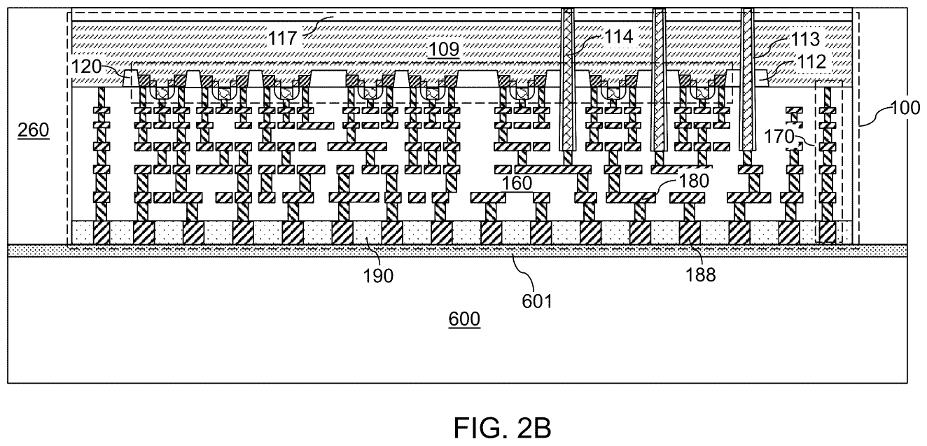

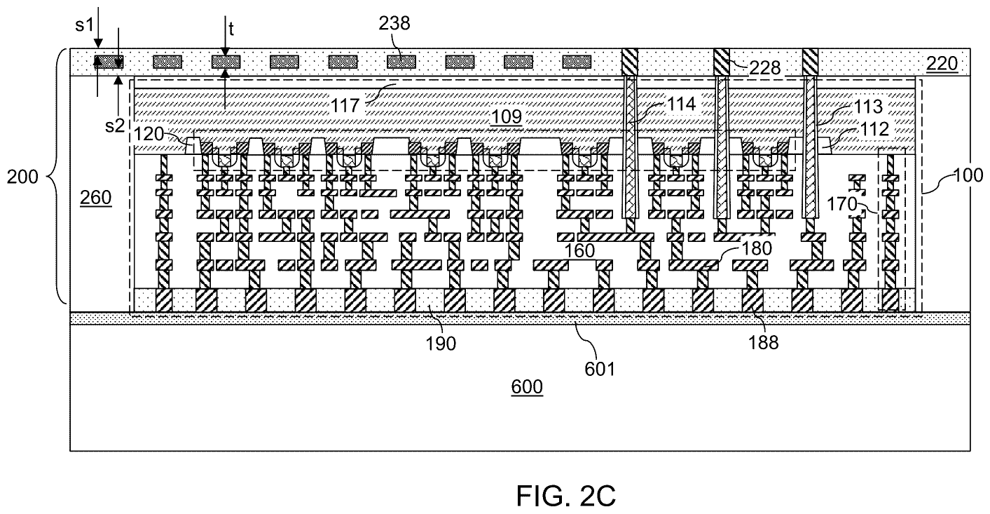

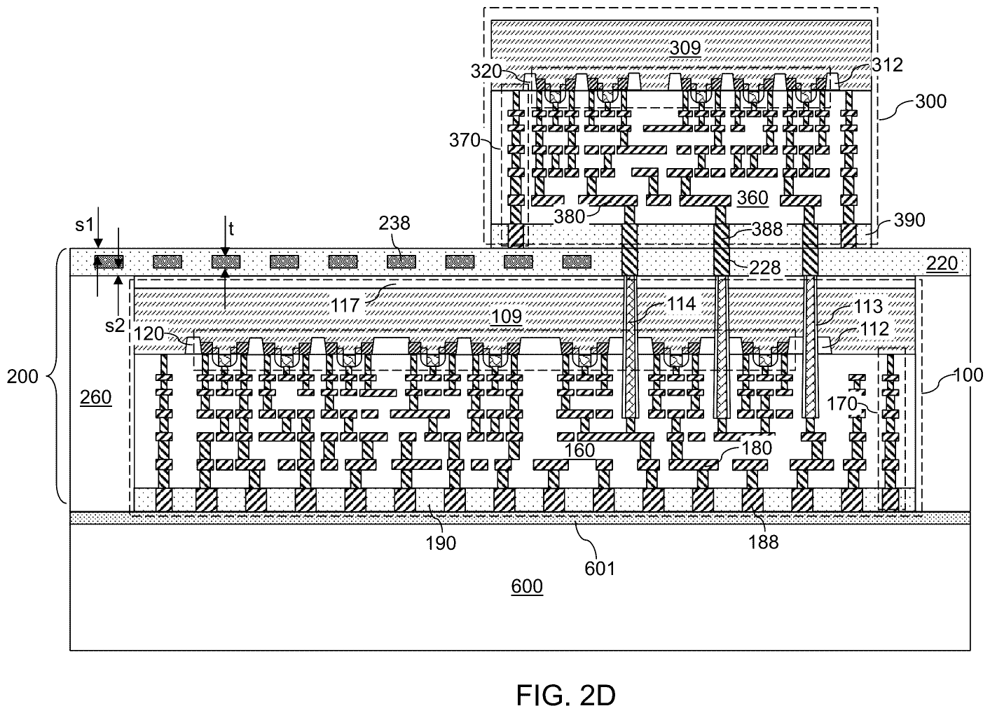

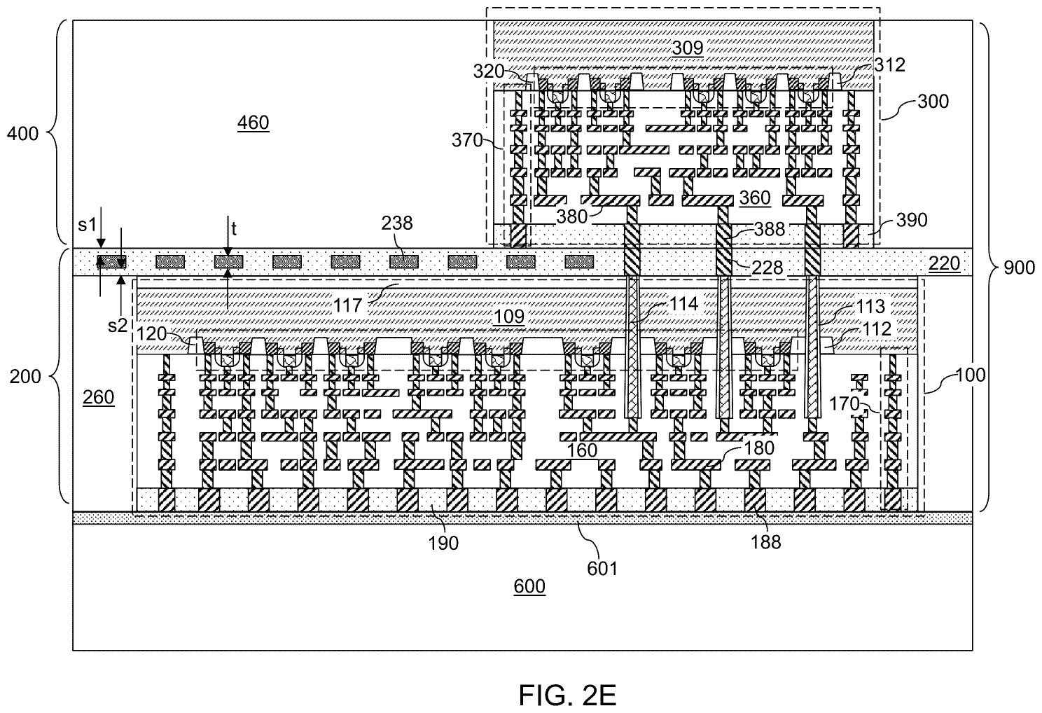

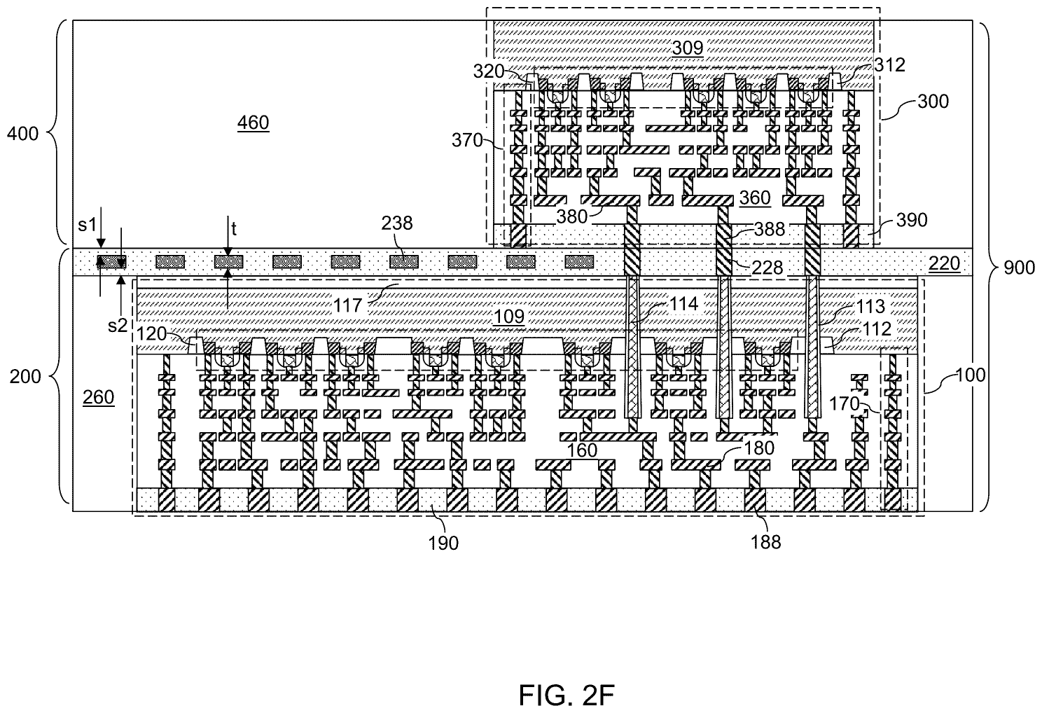

FIGS. 2A-2F are sequential vertical cross-sectional views of a unit area of the exemplary structure during formation of a reconstituted wafer including a two-dimensional array of composite dies 900 having a first configuration and singulation into discrete composite dies 900 according to an aspect of the present disclosure.

Referring to FIG. 2A, a vertical cross-sectional view of a unit area of the exemplary structure of FIG. 1 is illustrated. In the illustrated example, the first semiconductor die 100 is attached to the carrier substrate 600 through an adhesive layer 601, which may be a thermally-decomposable adhesive layer such as a polyimide layer, or may be an ultraviolet-decomposable adhesive layer such as an ultraviolet-sensitive tape.

The first semiconductor die 100 may comprise a first semiconductor substrate 109, first semiconductor devices 120 located on the first semiconductor substrate 109, first metal interconnect structures 180 formed within first dielectric material layers 160, a first front bonding-level dielectric layer 190, and package bonding structures 188 formed within the first front bonding-level dielectric layer 190. The package bonding structures 188 function as bonding structures of the composite die to be subsequently formed, and may be configured for solder-mediated bonding (such as chip connection bonding, i.e., microbump bonding, or controlled collapse chip connection bonding, i.e., C4 bonding) or may be configured for metal-to-metal bonding. A first-die edge seal ring structure 170 may vertically extend through the first dielectric material layers 160 and the first front bonding-level dielectric layer 190, and may laterally surround the entirety of the first metal interconnect structures 180.

The first semiconductor devices 120 may comprise any semiconductor device known in the art such as field effect transistors and passive devices. First shallow trench isolation structures 112 may be provided within the first semiconductor substrate 109 such that neighboring pairs of first semiconductor devices 120 may be electrically isolated from each other. The first semiconductor die 100 may comprise through-substrate via (TSV) structures 114 which vertically extends through the first semiconductor substrate 109 and optionally through a subset of the first dielectric material layers 160. The TSV structures 114 may be electrically isolated from the first semiconductor substrate 109 by dielectric liners 113. A first backside dielectric layer 117 may be provided on the backside of the first semiconductor substrate 109. In one embodiment, the TSV structures 114 may be arranged in a periodic pattern having a same periodicity as the pattern of first bonding pads to be subsequently formed over the first backside dielectric layer 117. Each of the sidewalls of the first semiconductor die 100 may be physically exposed.

Referring to FIG. 2B, a first molding compound may be applied to the gaps between neighboring pairs of the first semiconductor dies 100. The first molding compound may include an epoxy-containing compound that may be hardened (i.e., cured) to provide a dielectric material portion having sufficient stiffness and mechanical strength. The first molding compound may include epoxy resin, hardener, silica (as a filler material), and other additives. The first molding compound may be provided in a liquid form or in a solid form depending on the viscosity and flowability. Liquid first molding compound provides better handling, good flowability, less voids, better fill, and less flow marks. Solid molding compound provides less cure shrinkage, better stand-off, and less die drift. A high filler content (such as 85% in weight) within a molding compound may shorten the time in mold, lower the mold shrinkage, and reduce the mold warpage. Uniform filler size distribution in the molding compound may reduce flow marks, and may enhance flowability. The curing temperature of the molding compound may be lower than the release (debonding) temperature of the adhesive layer 601 in embodiments in which the adhesive layer 601 includes a thermally debonding material. For example, the curing temperature of the first molding compound may be in a range from 125° C. to 150° C.

The first molding compound may be cured at a curing temperature to form a first molding compound matrix 260 that laterally surrounds the two-dimensional array of the first semiconductor dies 100. The first molding compound matrix 260 comprise a plurality of first molding compound die frames that are interconnected to one another. Each first molding compound die frame is a portion of the first molding compound matrix 260 that is located within an area of a repetition unit within a two-dimensional periodic array of structures overlying the carrier substrate 600. Thus, each first molding compound die frame laterally surrounds and embeds a respective first semiconductor die 100.

Portions of the first molding compound matrix 260 that overlie the horizontal plane including the top surfaces of the first semiconductor dies 100 may be removed by a planarization process. For example, the portions of the first molding compound matrix 260 that overlies the horizontal plane may be removed using a chemical mechanical planarization (CMP). The combination of the remaining portion of the first molding compound matrix 260 and the array of first semiconductor dies 100 comprises a reconstituted wafer. Each portion of the first molding compound matrix 260 located within a unit area constitutes a first molding compound die frame. Generally, a first molding compound matrix 260 may be formed around a first semiconductor die 100 such that a top surface of the first molding compound matrix 260 is coplanar with a top dielectric surface of the first semiconductor die 100.

Referring to FIG. 2C, a combination of at least one bonding-level dielectric layer 220, first bonding pads 228, and dummy pads 238 may be formed over the first semiconductor die 100 and the first molding compound matrix 260. Each of the first bonding pads 228 may be formed directly on a respective conductive structure (such as a through-substrate via structure 114) within the first semiconductor die 100. Each portion of the exemplary structure within a unit area is herein referred to as a first molded die unit 200, which includes a first die set of a first semiconductor die 100 and portions of the first molding compound matrix 260 and the combination of the at least one bonding-level dielectric layer 220, first bonding pads 228, and dummy pads 238 that are located within a unit area.

Generally, each of the dummy pads 238 may have the same material composition as, or may have a different material composition than, the first bonding pads 228. In one embodiment, all of the dummy pads 238 may have the same material composition as the first bonding pads 228. In another embodiment, all of the dummy pads 238 may have a different material composition than the first bonding pads 228. In yet another embodiment, a first subset of the dummy pads 238 may have the same material composition as the first bonding pads 228, and a second subset of the dummy pads 238 may have a different material composition than the first bonding pads 228. In the configuration illustrated in FIG. 2C, each of the dummy pads 238 has a different material composition than the first bonding pads 228.

The at least one bonding-level dielectric layer 220 may comprise a single bonding-level dielectric layer 220, or may comprise a plurality of bonding-level dielectric layers 220. Each dummy pad 238 may have a respective thickness t, which is not greater than, and may be less than, the thickness of the at least one bonding-level dielectric layer 220. Each of the dummy pads 238 may have the same thickness t. Alternatively, the dummy pads 238 may comprise a first subset of the dummy pads 238 having a first thickness, a second subset of the dummy pads 238 having a second thickness that is different from the first thickness, etc.

Generally, each of the dummy pads 238 may have a top surface that is vertically offset from a horizontal plane that includes top surfaces of the first bonding pads 228, or may have a top surface that is formed within the horizontal plane that includes the top surfaces of the first bonding pads 228. In some embodiments, a first subset of the dummy pads 238 may have a top surface that is vertically offset from a horizontal plane including top surfaces of the first bonding pads 228, and a second subset of the dummy pads 238 may have a top surface that is formed within the horizontal plane including the top surfaces of the first bonding pads 228. In the configuration illustrated in FIG. 2C, each of the dummy pads 238 has a top surface that is vertically offset from a horizontal plane including top surfaces of the first bonding pads 228. In embodiments in which the dummy pads 238 have top surfaces that are vertically offset from the horizontal plane including the top surfaces of the first bonding pads 228, the vertical distance between the top surfaces of the dummy pads 238 and the horizontal plane including the top surfaces of the first bonding pads 228 is herein referred to as a first spacing s1, or an upper spacing.

Generally, each of the dummy pads 238 may have a bottom surface that is vertically offset from a horizontal plane that includes the bottom surfaces of the first bonding pads 228, or may have a bottom surface that is formed within the horizontal plane that includes the bottom surfaces of the first bonding pads 228. In some embodiments, a first subset of the dummy pads 238 may have a bottom surface that is vertically offset from a horizontal plane including bottom surfaces of the first bonding pads 228, and a second subset of the dummy pads 238 may have a bottom surface that is formed within the horizontal plane including the bottom surfaces of the first bonding pads 228. In the configuration illustrated in FIG. 2C, each of the dummy pads 238 has a bottom surface that is vertically offset from a horizontal plane including bottom surfaces of the first bonding pads 228. In embodiments in which the dummy pads 238 have bottom surfaces that are vertically offset from the horizontal plane including the bottom surfaces of the first bonding pads 228, the vertical distance between the bottom surfaces of the dummy pads 238 and the horizontal plane including the bottom surfaces of the first bonding pads 228 is herein referred to as a second spacing s2, or a lower spacing.

Referring to FIG. 2D, second semiconductor dies 300 having second bonding pads 388 may be bonded to a respective one of the first semiconductor dies 100 by metal-to-metal bonding. Each second semiconductor die 300 may be bonded to a respective first semiconductor die 100 by performing a bonding process that bonds the second bonding pads 388 of the second semiconductor die 300 to the first bonding pads 228 within a respective unit area containing the first semiconductor die 100 by metal-to-metal bonding such that a first subset of the dummy pads 238 has an areal overlap in a plan view with the second semiconductor die 300.

Each second semiconductor die 300 may comprise a second semiconductor substrate 309, second semiconductor devices 320 located on the second semiconductor substrate 309, second metal interconnect structures 380 formed within second dielectric material layers 360, a second front bonding-level dielectric layer 390, and second bonding pads 388 formed within the second front bonding-level dielectric layer 390. The second bonding pads 388 may be configured for metal-to-metal bonding such as copper-to-copper bonding. As used herein, metal-to-metal bonding refers to the direct bonding of metal surfaces without the use of intermediate adhesives or solders. Metal-to-metal bonding may be provided through thermocompression bonding and/or diffusion bonding between two metallic surfaces that are in direct contact with each other by performing an anneal process at an elevated temperature.

A second-die edge seal ring structure 370 (which may also be referred to as an edge seal ring structure 370) may vertically extend through the second dielectric material layers 360 and the second front bonding-level dielectric layer 390, and may laterally surround the entirety of the second metal interconnect structures 380. The second semiconductor devices 320 may comprise any semiconductor device known in the art such as field effect transistors and passive devices. Second shallow trench isolation structures 312 may be provided within the second semiconductor substrate 309 such that neighboring pairs of second semiconductor devices 320 are electrically isolated from each other. All of the sidewalls of the second semiconductor die 300 may be physically exposed.

The second bonding pads 388 may be bonded to the first bonding pads 228 through metal-to-metal bonding such as copper to copper bonding. Additionally, a horizontal bottom surface of the second front bonding-level dielectric layer 390 may be bonded to a topmost surface of the at least one bonding-level dielectric layer 220 by dielectric-to-dielectric bonding such as silicon oxide-to-silicon oxide bonding. In an illustrative example, the second bonding pads 388 of the second semiconductor die 300 may be aligned to the first bonding pads 228 of the first molded die unit 200, and a thermocompressive bonding process may be performed to bond mating pairs of the first bonding pads 228 and the second bonding pads 388.

According to an aspect of the present disclosure, a first subset of the dummy pads 238 has an areal overlap in a plan view (such as a top-down view along a vertical direction) with the second semiconductor die 300. A second subset of the dummy pads 238 does not have any areal overlap in the plan view with the second semiconductor die 300.

In one embodiment, the second semiconductor die 300 comprises an edge seal ring structure 370 that extends continuously along all sidewalls of the second semiconductor die 300. In one embodiment, at least one dummy pad 238 within the first subset of the dummy pads 238 overlaps with the edge seal ring structure 370 in the plan view. Additionally or alternatively, at least one dummy pad 238 within the first subset of the dummy pads 238 is at least partly within an area enclosed by the edge seal ring structure 370 in the plan view. Additionally or alternatively, at least one dummy pad 238 within the first subset of the dummy pads 238 is located at least partly within a frame-shaped area located between an outer periphery of the edge seal ring structure 370 and sidewalls of the second semiconductor die 300 in the plan view.

Referring to FIG. 2E, a second molding compound matrix 460 may be formed around the second semiconductor dies 300. Specifically, a second molding compound may be applied to the gaps between neighboring pairs of the second semiconductor dies 300. The second molding compound may comprise any material that may be used as the first molding compound. Generally, the second molding compound and the first molding compound may have the same material composition or may have different material compositions. The second molding compound may be cured at a curing temperature to form a second molding compound matrix 460 that laterally surrounds the two-dimensional array of the second semiconductor dies 300. The second molding compound matrix 460 comprise a plurality of second molding compound die frames that are interconnected to one another. Each second molding compound die frame is a portion of the second molding compound matrix 460 that is located within an area of a repetition unit within a two-dimensional periodic array of structures overlying the carrier substrate 600. Thus, each second molding compound die frame laterally surrounds and embeds a respective second semiconductor die 300.

Portions of the second molding compound matrix 460 that overlie the horizontal plane including the top surfaces of the second semiconductor dies 300 may be removed by a planarization process. For example, the portions of the second molding compound matrix 460 that overlies the horizontal plane may be removed using a chemical mechanical planarization (CMP). The combination of the remaining portion of the second molding compound matrix 460 and the array of second semiconductor dies 300 comprises second molded die units 400. Each second molded die unit 400 comprises a second semiconductor die 300 and a portion of the second molding compound matrix 460 located within a unit area. Each portion of the second molding compound matrix 460 located within a unit area constitutes a second molding compound die frame. Generally, a second molding compound matrix 460 may be formed around a second semiconductor die 300 such that a top surface of the second molding compound matrix 460 is coplanar with a top surface of the second semiconductor die 300. Each vertical stack of a first molded die unit 200 and a second molded die unit 400 constitutes a composite die 900. A two-dimensional array of composite dies 900 may be formed over the carrier substrate 600.

Referring to FIG. 2F, the carrier substrate 600 may be detached from a reconstituted wafer including a two-dimensional array of composite dies 900 by decomposing the adhesive layer 601. A thermal anneal process or an ultraviolet irradiation process may be used to decompose the adhesive layer 601. A suitable clean process may be performed to clean the physically exposed surfaces of the first front bonding-level dielectric layer 190 and the package bonding structures 188.

The reconstituted wafer may be diced along dicing channels to singulate the composite dies 900. Each composite die 900 comprises an assembly of a first semiconductor die 100; a first molding compound matrix 260 (which is a first molding compound die frame); a combination of at least one bonding-level dielectric layer 220, first bonding pads 228, and dummy pads 238; a second semiconductor die 300 including second bonding pads 388 that are bonded to the first bonding pads 228 via metal-to-metal bonding; and a second molding compound matrix 460 (which is a second molding compound die frame).

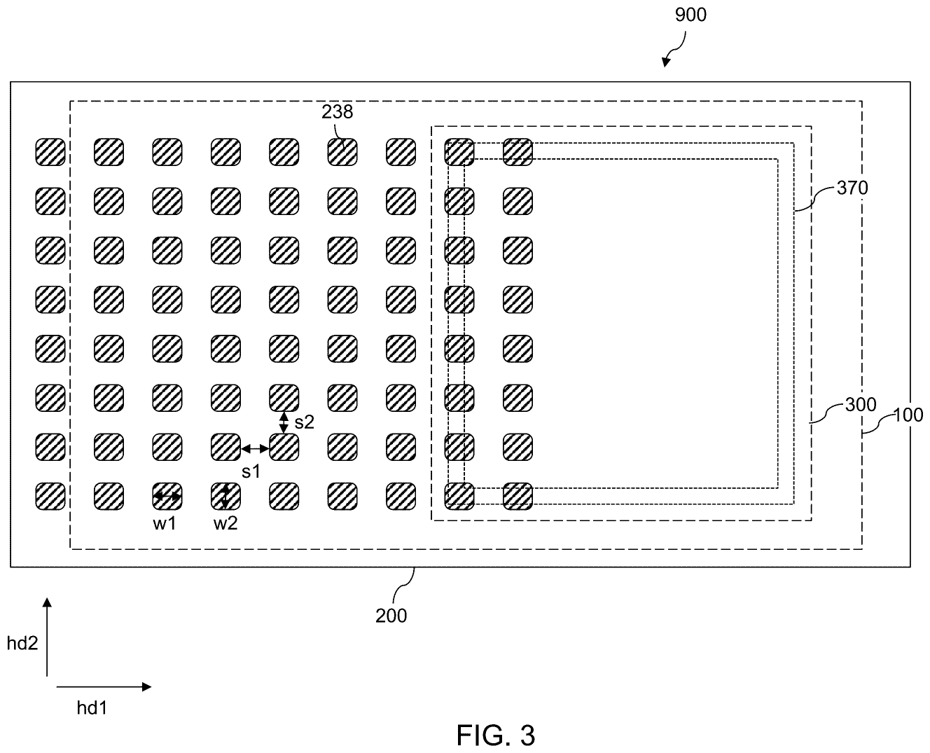

Referring to FIG. 3, a see-through top-down view of a composite die 900 having the first configuration is illustrated. The second semiconductor die 300 may have an area that is located entirely within the area of the first semiconductor die 100 in the plan view. As discussed above, the second semiconductor die 300 may comprises an edge seal ring structure 370 that extends continuously along all sidewalls of the second semiconductor die 300. In one embodiment, at least one dummy pad 238 within the first subset of the dummy pads 238 overlaps with the edge seal ring structure 370 in the plan view. Additionally or alternatively, at least one dummy pad 238 within the first subset of the dummy pads 238 is at least partly within an area enclosed by the edge seal ring structure 370 in the plan view. In other words, the at least one dummy pad 238 within the first subset of the dummy pads 238 may be at least partly within the area defined by inner sidewalls of the edge seal ring structure 370 in the plan view. Additionally or alternatively, at least one dummy pad 238 within the first subset of the dummy pads 238 is located at least partly within a frame-shaped area located between an outer periphery of the edge seal ring structure 370 and sidewalls of the second semiconductor die 300 in the plan view. The outer periphery of the edge seal ring structure is defined by outermost sidewalls of the edge seal ring structure 370.

In one embodiment, each of the first semiconductor die 100 and the second semiconductor die 300 may have a respective pair of first sidewalls that laterally extend along a first horizontal direction hd1, and a respective pair of second sidewalls that laterally extend along a second horizontal direction hd2 that is perpendicular to the first horizontal direction hd2. In one embodiment, the dummy pads 238 may comprise at least one row of dummy pads 238 that are arranged along the second horizontal direction hd2 and/or at least one column of dummy pads 238 that are arranged along the first horizontal direction hd1. The shapes of the dummy pads 238 may be identical to one another, or may differ from one another. For example, each of the dummy pads 238 may have a respective shape of a circle, a rectangle, a rounded rectangle, or any other two-dimensional curvilinear shape having a closed periphery. In some embodiments, one or more of the dummy pads 238 may have a respective opening therethrough.

The first lateral dimension w1 (such as the diameter, the length of a side, or any other maximum dimension along a lateral direction) of each dummy pad 238 along the first horizontal direction hd1 may be in a range from 0.1 micron to 10 mm, such as from 0.3 micron to 30 microns, although lesser and greater lateral dimensions may also be used. The second lateral dimension w2 of each dummy pad 238 along the second horizontal direction hd2 may be in a range from 0.1 micron to 10 mm, such as from 0.3 micron to 30 microns, although lesser and greater lateral dimensions may also be used. The first lateral spacing s1 between neighboring pairs of dummy pads 238 along the first horizontal direction hd1 may be in a range from 0.1 micron to 10 mm, such as from 0.3 micron to 30 microns, although lesser and greater lateral spacings may also be used. The second lateral spacing s2 between neighboring pairs of dummy pads 238 along the second horizontal direction hd2 may be in a range from 0.1 micron to 10 mm, such as from 0.6 micron to 60 microns, although lesser and greater lateral spacings may also be used. The thickness of each dummy pad 238 may be in a range from 0.1 micron to 100 microns, such as from 0.3 micron to 10 microns, although lesser and greater thicknesses may also be used.

The total number of the dummy pads 238 may be determined based on the stress loading that is generated during the bonding of the second semiconductor dies 300 to the first molded die units 200. Likewise, the loading factor, i.e., the ratio of the total area occupied by the dummy pads 238 to the total area of a top surface of a single first molded die unit 200, may be optimized based on the stress loading that is generated during the bonding of the second semiconductor dies 300 to the first molded die units 200. Generally, the loading factor may be in a range from 0.0001 to 0.1, although lesser and greater loading factors may also be used.

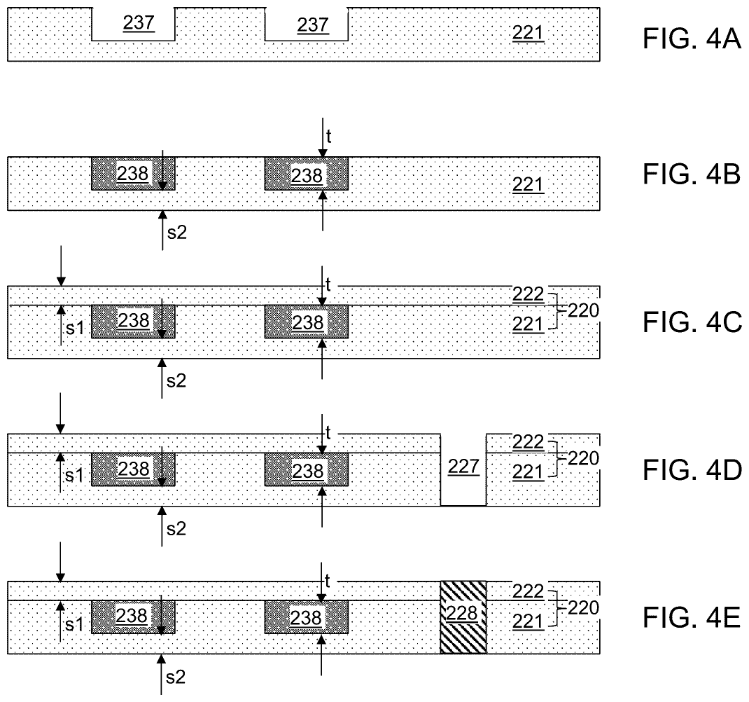

FIGS. 4A-4E are sequential vertical cross-sectional views of a region of the first configuration of the exemplary structure around at least one bonding-level dielectric layer 220 during formation of dummy pads 238 and first bonding pads 228 according to an embodiment of the present disclosure. FIGS. 4A-4E illustrate an exemplary sequence of processing steps that may be used to form the combination of the at least one bonding-level dielectric layer 220, the first bonding pads 228, and the dummy pads 238 at the processing steps of FIG. 2C.

Referring to FIG. 4A, a lower bonding-level dielectric layer 221 may be deposited over the reconstituted wafer including a two-dimensional array of first semiconductor dies 100 and the first molding compound matrix 260, i.e., the reconstituted wafer as provided at the processing steps of FIG. 2B. The lower bonding-level dielectric layer 221 may comprise any interlayer dielectric (ILD) material known in the art such as undoped silicate glass, a doped silicate glass, etc. The lower bonding-level dielectric layer 221 is a first subset of at least one bonding-level dielectric layer 220 described above. The thickness of the lower bonding-level dielectric layer 221 may be in a range from 0.2 microns to 200 microns, such as from 3 microns to 100 microns, although lesser and greater thicknesses may also be used.

A photoresist layer (not shown) may be applied over the lower bonding-level dielectric layer 221, and may be lithographically patterned to form openings in area in which the dummy pads 238 are to be subsequently formed. An anisotropic etch process may be performed to transfer the pattern of the openings in the photoresist layer into an upper portion of the lower bonding-level dielectric layer 221. Dummy-pad cavities 237 may be formed with a first depth, which may be the same as the thickness t of dummy pads 238 to be subsequently formed. The photoresist layer may be subsequently removed, for example, by ashing.

Referring to FIG. 4B, a first fill material having a first material composition is deposited into the dummy-pad cavities 237 by performing a first deposition process. The first fill material has a different material composition than the lower bonding-level dielectric layer 221. The first fill material may be different from, or may be the same as, a second fill material to be subsequently used to form the first bonding pads 228. The first fill material may comprise any, or a combination of, at least one metal (e.g., copper (Cu), aluminum (Al), etc.), at least one metallic compound material (e.g., titanium nitride (TiN), tantalum nitride (TaN), etc.), at least one organic fill material (e.g., polyimide, resin, a molding compound material, etc.), and a dielectric fill material (e.g., silicon nitride (SiN), silicon carbide (SiC), a dielectric metal oxide, etc.). In one embodiment, the first fill material may comprise, and/or may consist essentially of, at least one metal. In one embodiment, the first fill material may comprise, and/or may consist essentially of, at least one metallic compound material. In one embodiment, the first fill material may comprise, and/or may consist essentially of at least one organic fill material. In one embodiment, the first fill material may comprise, and/or may consist essentially of a dielectric fill material.

A first planarization process, such as a chemical mechanical polishing process, may be performed to remove excess portions of the first fill material from above the horizontal plane including the top surface of the lower bonding-level dielectric layer 221. Each remaining portion of the first fill material that fills a respective one of the dummy-pad cavities 237 constitutes a dummy pad 238. Each of the dummy pads 238 may have a thickness t, which may be in a range from 0.1 micron to 100 microns, such as from 0.3 micron to 10 microns, although lesser and greater thicknesses may also be used. The vertical spacing between the bottom surfaces of the dummy pads 238 and the horizontal plane including the bottom surface of the lower bonding-level dielectric layer 221 is the second spacing s2, or the lower spacing. The second spacing s2 may be in a range from 0.1 micron to 100 microns, such as from 0.3 micron to 10 microns, although lesser and greater thicknesses may also be used.

Referring to FIG. 4C, an upper bonding-level dielectric layer 222 may be deposited over the lower bonding-level dielectric layer 221. The upper bonding-level dielectric layer 222 may comprise any interlayer dielectric (ILD) material known in the art such as undoped silicate glass, a doped silicate glass, etc. The upper bonding-level dielectric layer 222 is a second subset of at least one bonding-level dielectric layer 220 described above. Thus, a second subset of the at least one bonding-level dielectric layer 220 may be deposited over the first subset of the at least one bonding-level dielectric layer 220. The thickness of the upper bonding-level dielectric layer 222 may be in a range from 0.1 microns to 100 microns, such as from 1 microns to 50 microns, although lesser and greater thicknesses may also be used. The thickness of the upper bonding-level dielectric layer 222 may be the same as the first spacing s1, or the upper spacing. The combination of the lower bonding-level dielectric layer 221 and the upper bonding-level dielectric layer 222 constitutes the at least one bonding-level dielectric layer 220 described above.

Referring to FIG. 4D, a photoresist layer (not shown) may be applied over the upper bonding-level dielectric layer 222, and may be lithographically patterned to form openings in area in which the first bonding pads 228 are to be subsequently formed. An anisotropic etch process may be performed to transfer the pattern of the openings in the photoresist layer through the entirety of the at least one bonding-level dielectric layer 220, i.e., through each layer of the at least one bonding-level dielectric layer 220. Bonding-pad cavities 227 having a second depth may be formed through the at least one bonding-level dielectric layer 220. The second depth may equal the total thickness of the at least one bonding-level dielectric layer 220. As such, the second thickness is greater than the first thickness of the dummy-pad cavities 237. The photoresist layer may be subsequently removed, for example, by ashing. In this illustrative example, the bonding-pad cavities 227 are formed after performing the first planarization process.

Referring to FIG. 4E, a second fill material having a second material composition is deposited into the bonding-pad cavities 227 by performing a second deposition process. The second fill material is different from the first fill material, and has a metallic composition that is conducive to metal-to-metal bonding. For example, the second fill material may comprise a combination of a thin metallic barrier liner material (such as TiN, TaN, WN, and/or MoN) and a copper fill material consisting essentially of copper.

A second planarization process, such as a chemical mechanical polishing process, may be performed to remove excess portions of the second fill material from above the horizontal plane including the topmost surface of the at least one bonding-level dielectric layer 220. Each remaining portion of the second fill material that fills a respective one of the bonding-pad cavities 227 constitutes a first bonding pad 228. Each of the first bonding pads 228 may have a thickness that equals the total thickness of the at least one bonding-level dielectric layer 220. Generally, each of the first bonding pads 228 may be formed directly on a respective conductive structure (such as a through-substrate via structure 114) within the first semiconductor die 100 as described with reference to FIG. 2C.

Generally speaking, the dummy pads 238 may be formed by depositing and patterning a first fill material within a first subset of at least one bonding-level dielectric layer 220; and the first bonding pads 228 are formed by depositing and patterning a second fill material within the at least one bonding-level dielectric layer 220 such that each of the first bonding pads 228 vertically extend from a bottommost surface of the at least one bonding-level dielectric layer 220 to a topmost surface of the at least one bonding-level dielectric layer 220. The first subset of the at least one bonding-level dielectric layer 220 may be less than, or may be the same as, the entirety of the at least one bonding-level dielectric layer. The second fill material may be the same as, or may be different from, the first fill material. The first fill material is deposited by a first deposition process, and is planarized by a first planarization process to form the dummy pads 238; and the second fill material is deposited by a second deposition process and is planarized by a second planarization process to form the first bonding pads 228. Generally, the second deposition process may be the same as, or may be different from, the first deposition process. Generally, the second planarization process may be the same as, or may be different from, the first planarization process.

In some embodiments, a second subset of the at least one bonding-level dielectric layer 220 may be deposited over the dummy pads 238 (for example, as illustrated in FIG. 4C); and bonding-pad cavities 227 may be formed through the second subset and through the first subset. The first bonding pads 228 are formed in the bonding-pad cavities 227.

The sequence of processing steps described with reference to FIGS. 4A-4E may be modified in various manners to provide alternative configurations for the dummy pads 238 and the first bonding pads 228. Thus, many alternative configurations may be used to form the combination of the at least one bonding-level dielectric layer 220, the first bonding pads 228, and the dummy pads 238 over the first semiconductor die 100 and the first molding compound matrix 260

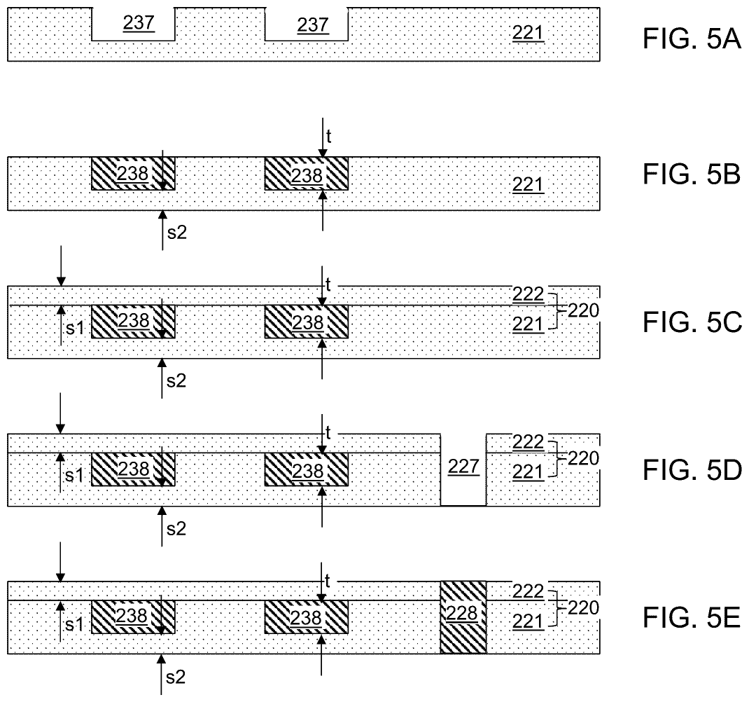

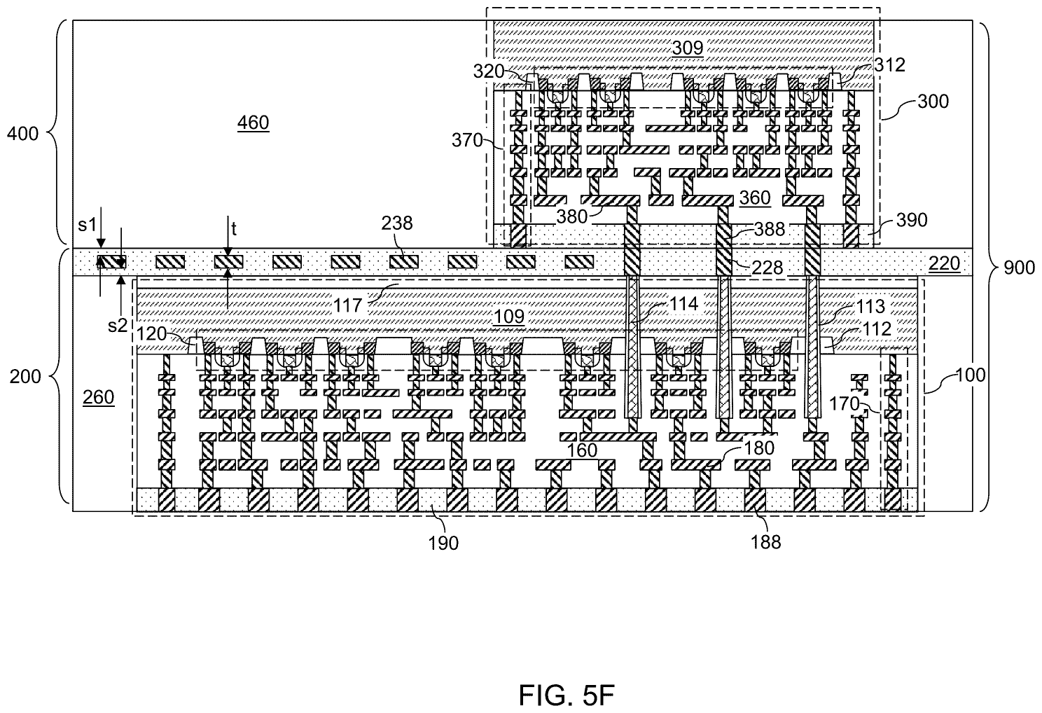

FIGS. 5A-5E are sequential vertical cross-sectional views of a region of a second configuration of the exemplary structure around at least one bonding-level dielectric layer 220 during formation of dummy pads 238 and first bonding pads 228 according to an embodiment of the present disclosure. FIG. 5F is a vertical cross-sectional view of a composite die 900 having the second configuration according to an embodiment of the present disclosure. The processing sequence illustrated in FIGS. 5A-5E may be derived from the processing sequence described with reference to FIGS. 4A-4E by using the same fill material for the first fill material and the second fill material. In this embodiment, the first fill material used during the processing sequence illustrated in FIGS. 5A-5E may be the same as the second fill material described with reference to FIG. 4E. Thus, the dummy pads 238 and the first bonding pads 228 in FIGS. 5E and 5F may comprise a same metal or a same set of metallic materials (such as a combination of a thin metallic barrier liner material (such as TiN, TaN, WN, and/or MoN) and a copper fill material consisting essentially of copper.

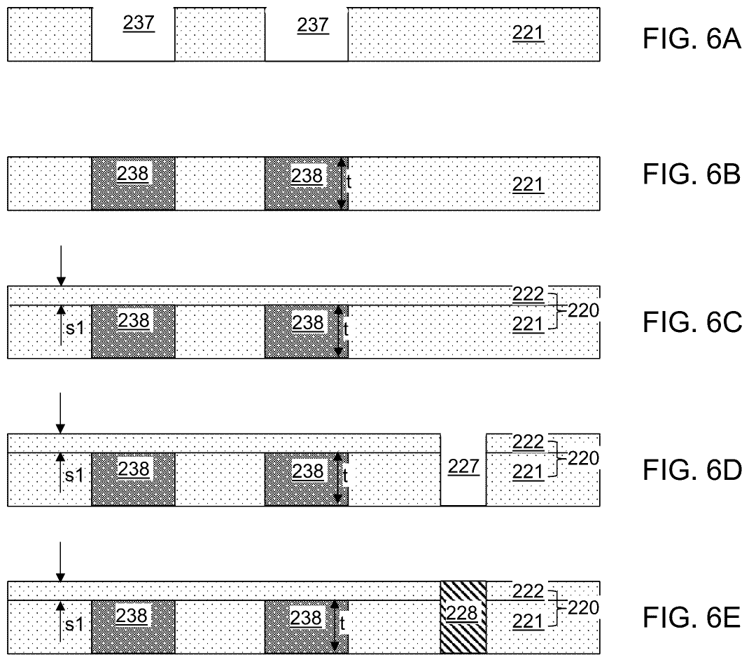

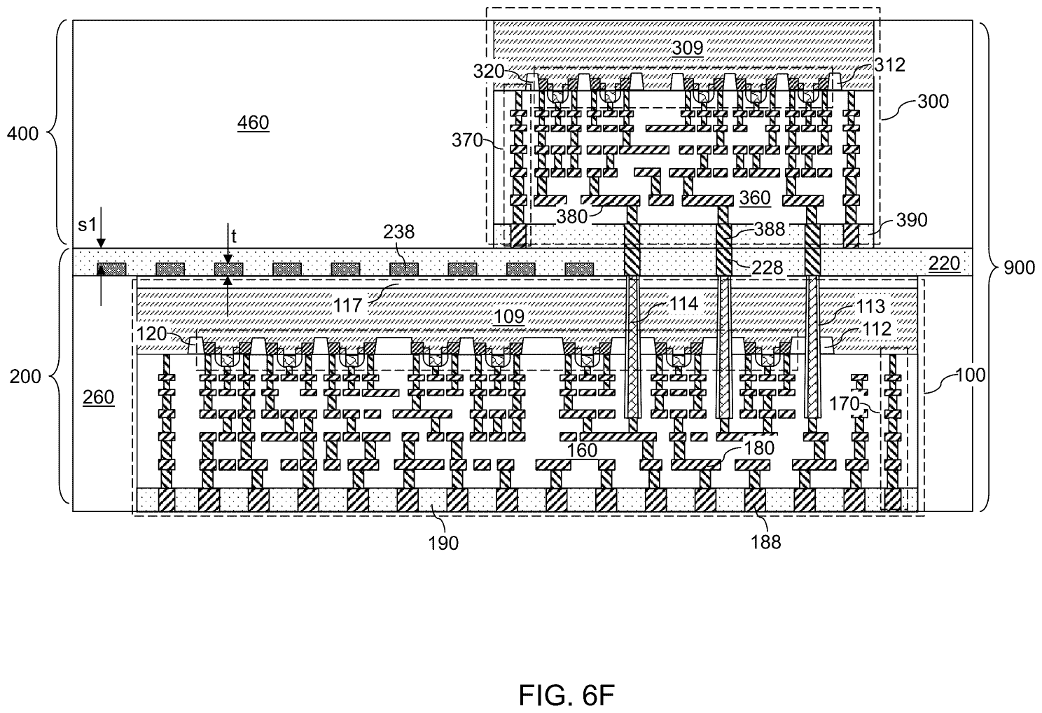

FIGS. 6A-6E are sequential vertical cross-sectional views of a region of a third configuration of the exemplary structure around at least one bonding-level dielectric layer 220 during formation of dummy pads 238 and first bonding pads 228 according to an embodiment of the present disclosure. FIG. 6F is a vertical cross-sectional view of a composite die 900 having the third configuration according to an embodiment of the present disclosure. The processing sequence illustrated in FIGS. 6A-6E may be derived from the processing sequence described with reference to FIGS. 4A-4E by increasing the depth of the dummy-pad cavities 237 so that the depth of the dummy-pad cavities 237 equals the thickness of the lower bonding-level dielectric layer 221. In other words, the second spacing s2, or the lower spacing, is zero. As a consequence, the thickness of each dummy pad 238 may equal the thickness of the lower bonding-level dielectric layer 221, and each dummy pad 238 may contact a horizontal surface of the first semiconductor die 100 (such as a surface of the first backside dielectric layer 117).

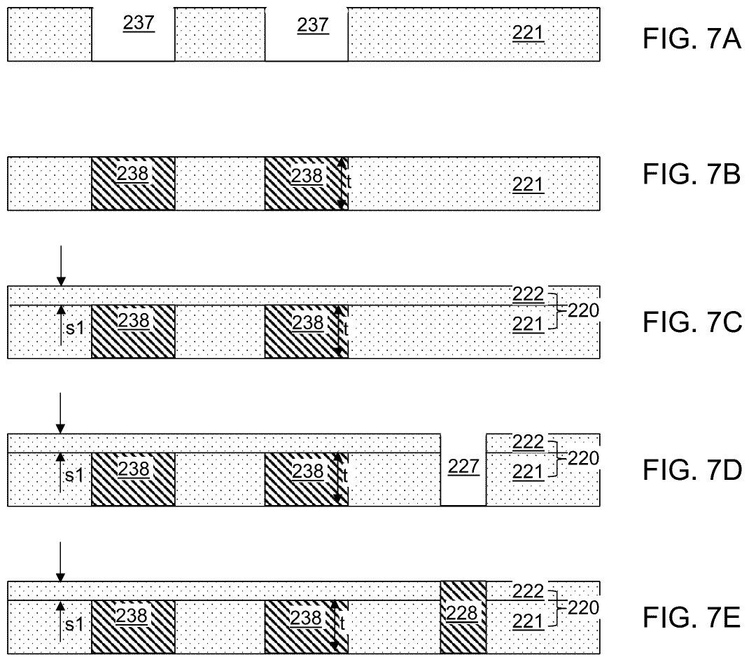

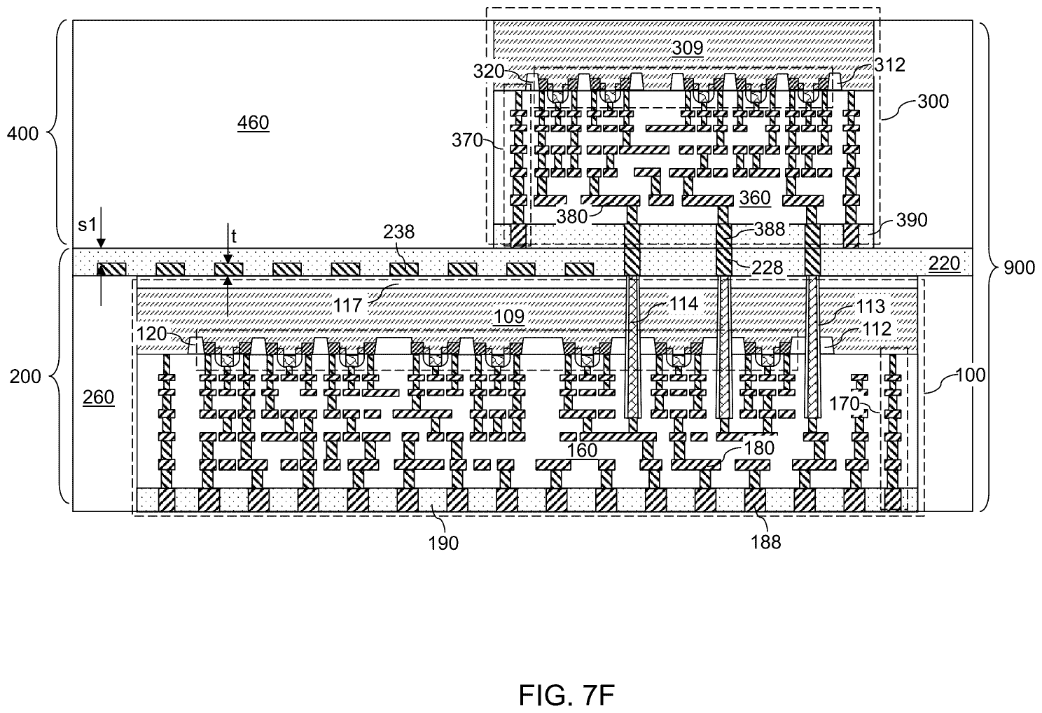

FIGS. 7A-7E are sequential vertical cross-sectional views of a region of a fourth configuration of the exemplary structure around at least one bonding-level dielectric layer 220 during the formation of dummy pads 238 and first bonding pads 228 according to an embodiment of the present disclosure. FIG. 7F is a vertical cross-sectional view of a composite die 900 having the fourth configuration according to an embodiment of the present disclosure. The processing sequence illustrated in FIGS. 7A-7E may be derived from the processing sequence described with reference to FIGS. 6A-6E by using the same fill material for the first fill material and the second fill material. In this embodiment, the first fill material used during the processing sequence illustrated in FIGS. 6A-6E may be the same as the second fill material described with reference to FIG. 4E. Thus, the dummy pads 238 and the first bonding pads 228 in FIGS. 7E and 7F may comprise a same metal or a same set of metallic materials (such as a combination of a thin metallic barrier liner material (such as TiN, TaN, WN, and/or MoN) and a copper fill material consisting essentially of copper.

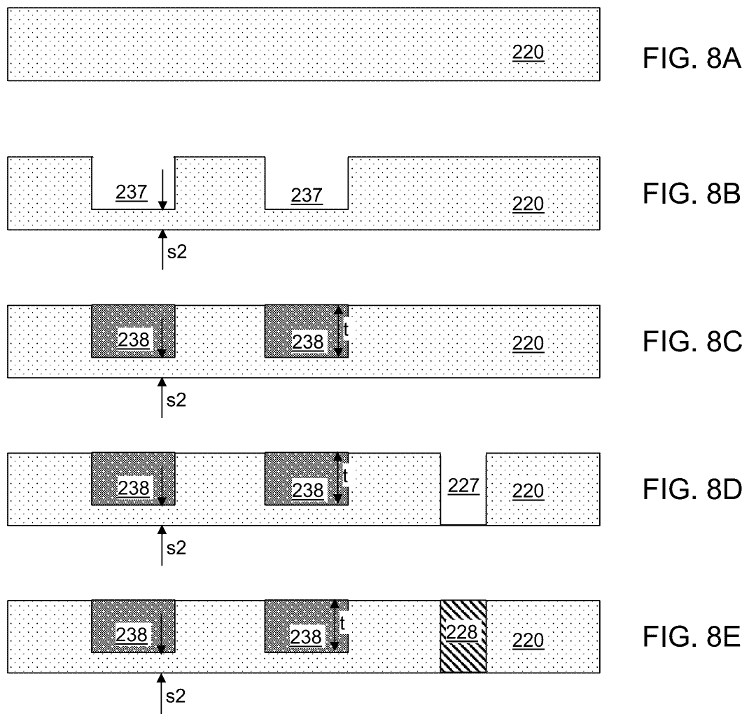

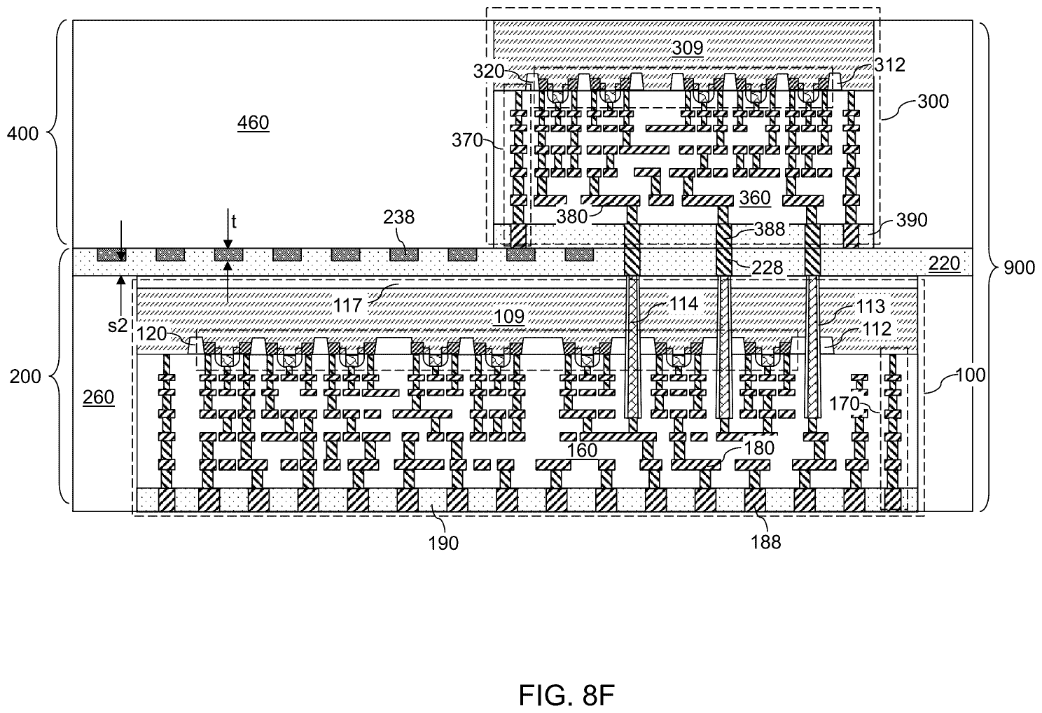

FIGS. 8A-8E are sequential vertical cross-sectional views of a region of a fifth configuration of the exemplary structure around at least one bonding-level dielectric layer 220 during the formation of dummy pads 238 and first bonding pads 228 according to an embodiment of the present disclosure. FIG. 8F is a vertical cross-sectional view of a composite die 900 having the fifth configuration according to an embodiment of the present disclosure. The processing sequence illustrated in FIGS. 8A-8E may be derived from the processing sequence described with reference to FIGS. 5A-5E by depositing the entirety of the at least one bonding-level dielectric layer 220 prior to formation of the dummy-pad cavities 237. In this embodiment, a single bonding-level dielectric layer may be used as the at least one bonding-level dielectric layer 220. The processing steps described with reference to FIG. 4C may be omitted, and the anisotropic etch process that forms the bonding-pad cavities 227 may be modified as needed to accommodate any change in the material composition and/or the thickness of the at least one bonding-level dielectric layer 220. In this configuration, the first vertical spacing s1, or the upper spacing, is zero. The top surfaces of the dummy pads 238 may be formed within the same horizontal plane as the top surfaces of the first bonding pads 228. The first fill material of the dummy pads 238 may be different from the second fill material (which is a metallic fill material) of the first bonding pads.

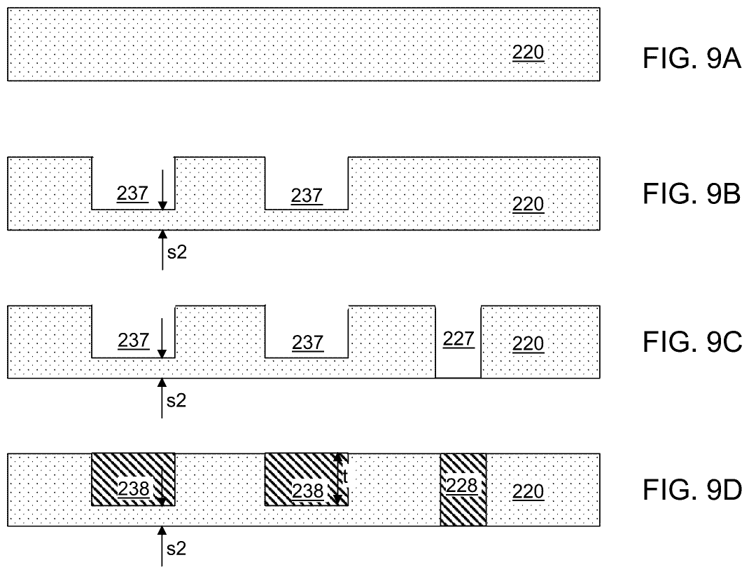

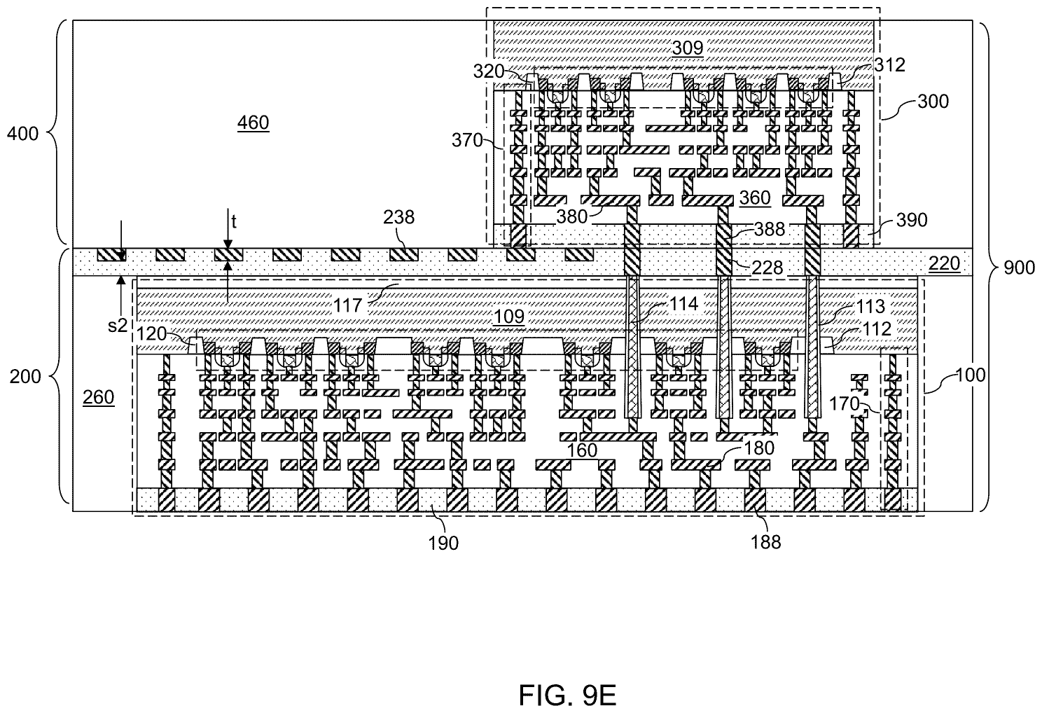

FIGS. 9A-9D are sequential vertical cross-sectional views of a region of a sixth configuration of the exemplary structure around at least one bonding-level dielectric layer 220 during the formation of dummy pads 238 and first bonding pads 228 according to an embodiment of the present disclosure. FIG. 9E is a vertical cross-sectional view of a composite die 900 having the sixth configuration according to an embodiment of the present disclosure. The processing sequence illustrated in FIGS. 9A-9D may be derived from the processing sequence described with reference to FIGS. 8A-8E by using the same fill material for the first fill material and the second fill material. In this embodiment, the dummy-pad cavities 237 and the bonding-pad cavities 227 may be formed, in any order, in the at least one bonding-level dielectric layer 220. The first fill material and the second fill material are the same, and thus, are deposited during a same deposition step. The planarization of the first fill material and the planarization of the second fill material may be performed simultaneously using a single planarization process, such as a chemical mechanical polishing process, to form the dummy pads 238 and the first bonding pads 228. Thus, the dummy pads 238 and the first bonding pads 228 in FIGS. 7E and 7F may comprise a same metal or a same set of metallic materials (such as a combination of a thin metallic barrier liner material (such as TiN, TaN, WN, and/or MoN) and a copper fill material consisting essentially of copper.

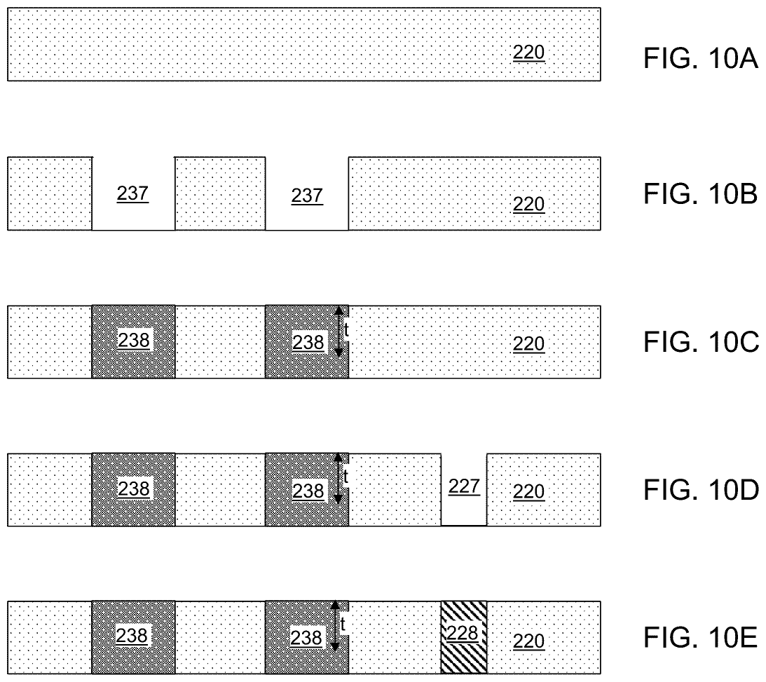

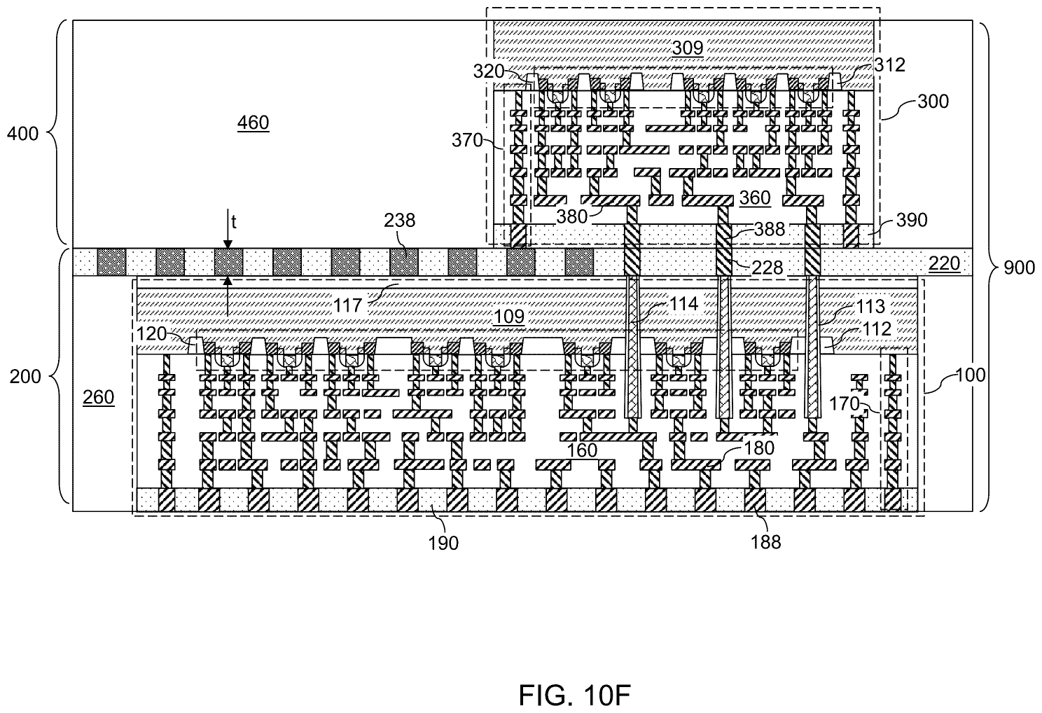

FIGS. 10A-10E are sequential vertical cross-sectional views of a region of a seventh configuration of the exemplary structure around at least one bonding-level dielectric layer 220 during the formation of dummy pads 238 and first bonding pads 228 according to an embodiment of the present disclosure. FIG. 10F is a vertical cross-sectional view of a composite die 900 having the seventh configuration according to an embodiment of the present disclosure. The processing sequence illustrated in FIGS. 10A-10E may be derived from the processing sequence described with reference to FIGS. 8A-8E by increasing the depth of the dummy-pad cavities 237 so that the depth of the dummy-pad cavities 237 equals the total thickness of the at least one bonding-level dielectric layer 220. In other words, the second spacing s2, or the lower spacing, is zero. The first spacing s1, or the upper spacing, is also zero. As a consequence, the thickness of each dummy pad 238 may equal the thickness of the at least one bonding-level dielectric layer 220, and each dummy pad 238 may contact a horizontal surface of the first semiconductor die 100 (such as a surface of the first backside dielectric layer 117). The dummy pads 238 and the first bonding pads 228 may have the same thickness which equals the thickness of the at least one bonding-level dielectric layer 220.

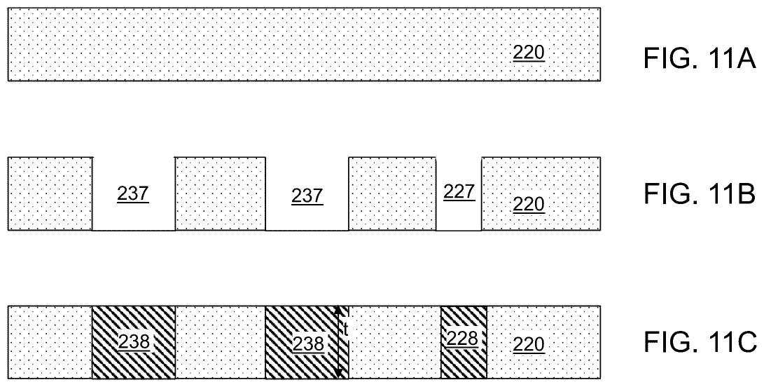

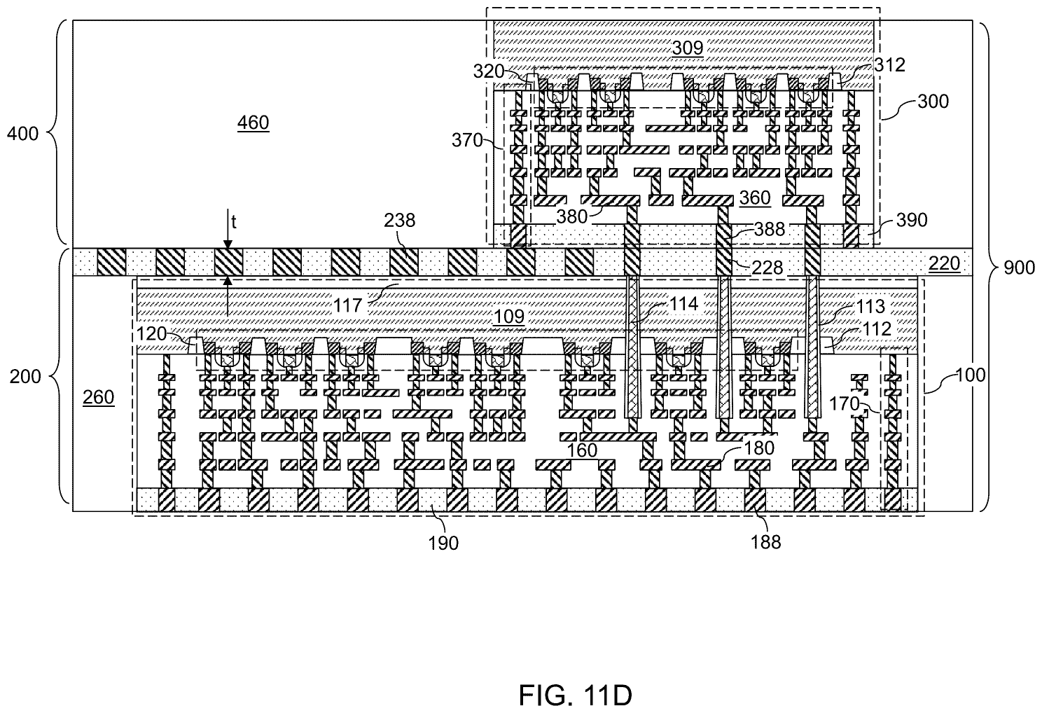

FIGS. 11A-11C are sequential vertical cross-sectional views of a region of an eighth configuration of the exemplary structure around at least one bonding-level dielectric layer 220 during the formation of dummy pads 238 and first bonding pads 228 according to an embodiment of the present disclosure. FIG. 11D is a vertical cross-sectional view of a composite die 900 having the eighth configuration according to an embodiment of the present disclosure. The processing sequence illustrated in FIGS. 11A-11C may be derived from the processing sequence described with reference to FIGS. 10A-10E by using the same fill material for the first fill material and the second fill material. In this embodiment, the dummy-pad cavities 237 and the bonding-pad cavities 227 may be formed simultaneously through the at least one bonding-level dielectric layer 220 by using a same lithographically patterned etch mask (such as a patterned photoresist layer) and a same anisotropic etch process. The first fill material and the second fill material are the same, and thus, are deposited during a same deposition step. The planarization of the first fill material and the planarization of the second fill material may be performed simultaneously using a single planarization process, such as a chemical mechanical polishing process, to form the dummy pads 238 and the first bonding pads 228. Thus, the dummy pads 238 and the first bonding pads 228 in FIGS. 7E and 7F may have the same thickness, and may comprise a same metal or a same set of metallic materials (such as a combination of a thin metallic barrier liner material (such as TiN, TaN, WN, and/or MoN) and a copper fill material consisting essentially of copper.

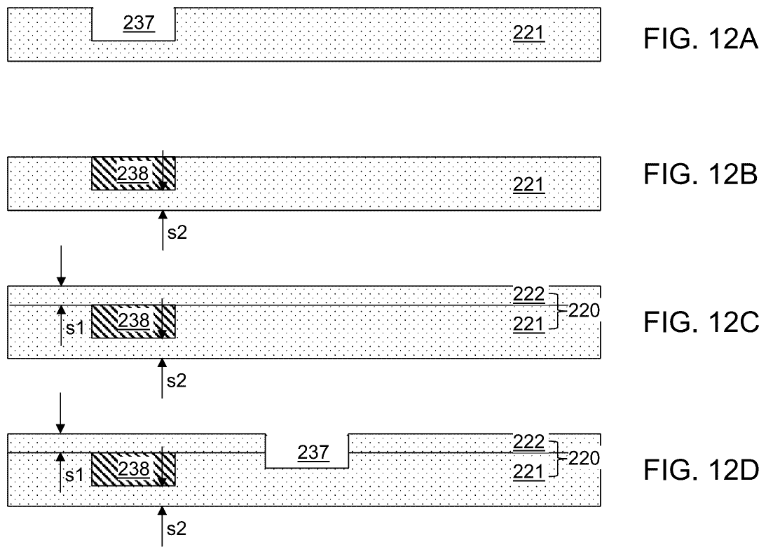

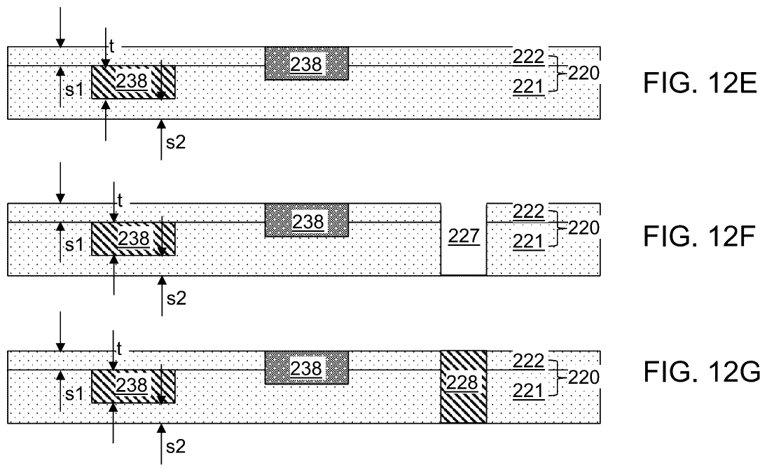

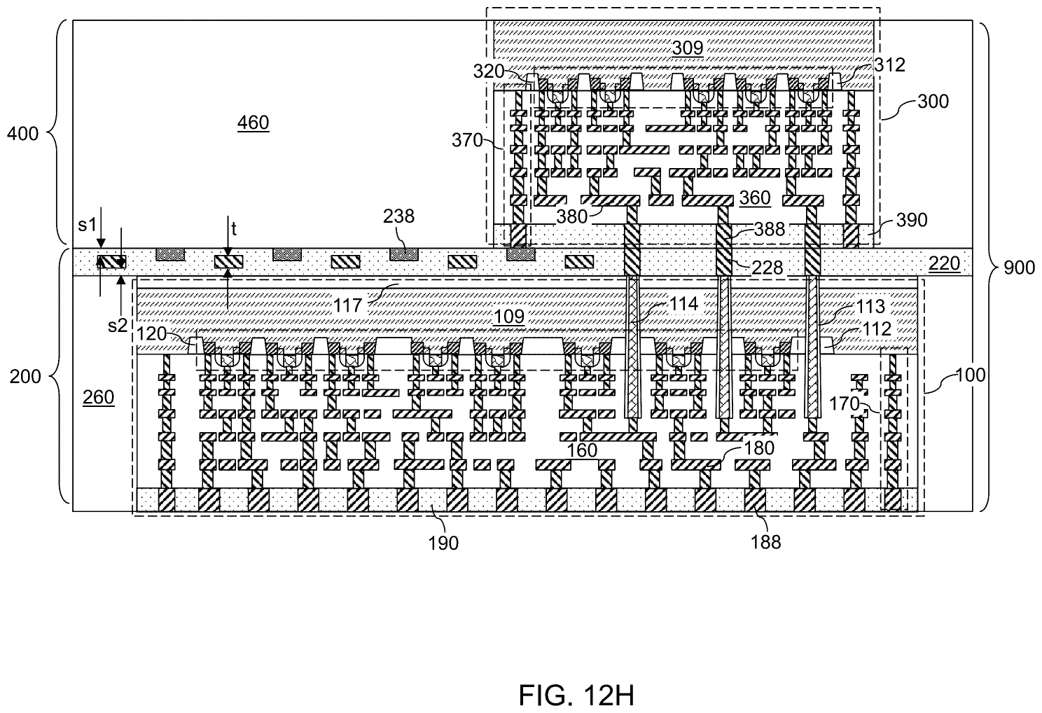

FIGS. 12A-12G are sequential vertical cross-sectional views of a region of a ninth configuration of the exemplary structure around at least one bonding-level dielectric layer 220 during the formation of dummy pads 238 and first bonding pads 228 according to an embodiment of the present disclosure. FIG. 12H is a vertical cross-sectional view of a composite die 900 having the ninth configuration according to an embodiment of the present disclosure. The processing sequence illustrated in FIGS. 12A-12G may be derived from the processing sequence described with reference to FIGS. 4A-4E by modifying the pattern of the dummy-pad cavities 237 formed at the processing step of FIG. 4A so that only a first subset of the dummy-pad cavities 237 is patterned at the processing step illustrated in FIG. 12A. Subsequently, the processing steps described with reference to FIGS. 4B and 4C may be performed at the processing steps of FIGS. 12B and 12C, respectively. A first subset of the dummy pads 238 is formed within the first subset of the dummy-pad cavities 237. Generally, the first subset of the dummy pads 238 may include the same material as, or may include a different material from, the material of the first bonding pads 228 to be subsequently formed. In the ninth configuration illustrated in FIGS. 12A-12G, the first subset of the dummy pads 238 includes the same material as the first bonding pads 228 to be subsequently formed.

Referring to FIG. 12D, the processing step described with reference to FIG. 4A may be performed with a modification in an etch pattern so that a second subset of the dummy-pad cavities 237 is patterned. Thus, the top peripheries of the second subset of the dummy-pad cavities 237 is vertically offset relative to the top peripheries of the first subset of the dummy-pad cavities 237 by the first spacing s1, i.e., the upper spacing. The depth of the second subset of the dummy-pad cavities 237 which is formed at the processing step of FIG. 12D may be the same as, or may be different from, the depth of the first subset of the dummy-pad cavities 237 which is formed at the processing step of FIG. 12A.

Referring to FIGS. 12E-12G, the processing steps described with reference to FIGS. 4B, 4D, and 4E may be performed to form a second subset of the dummy pads 238 and the first bonding pads 228. Generally, the second subset of the dummy pads 238 may include the same material as, or may include a different material from, the material of the first bonding pads 228. In the ninth configuration illustrated in FIGS. 12A-12G, the second subset of the dummy pads 238 includes a different material from the material of the first bonding pads 228.

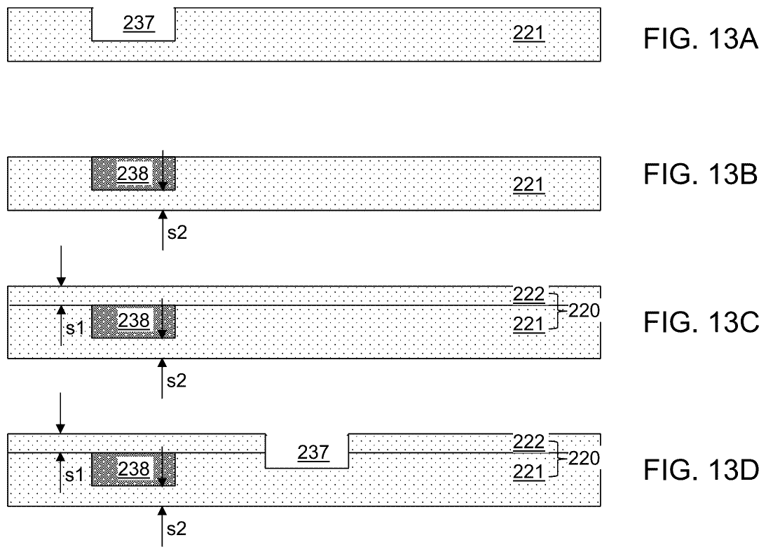

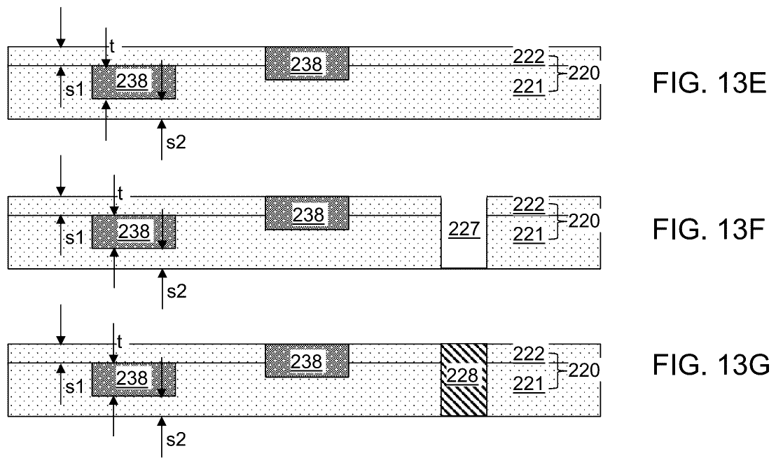

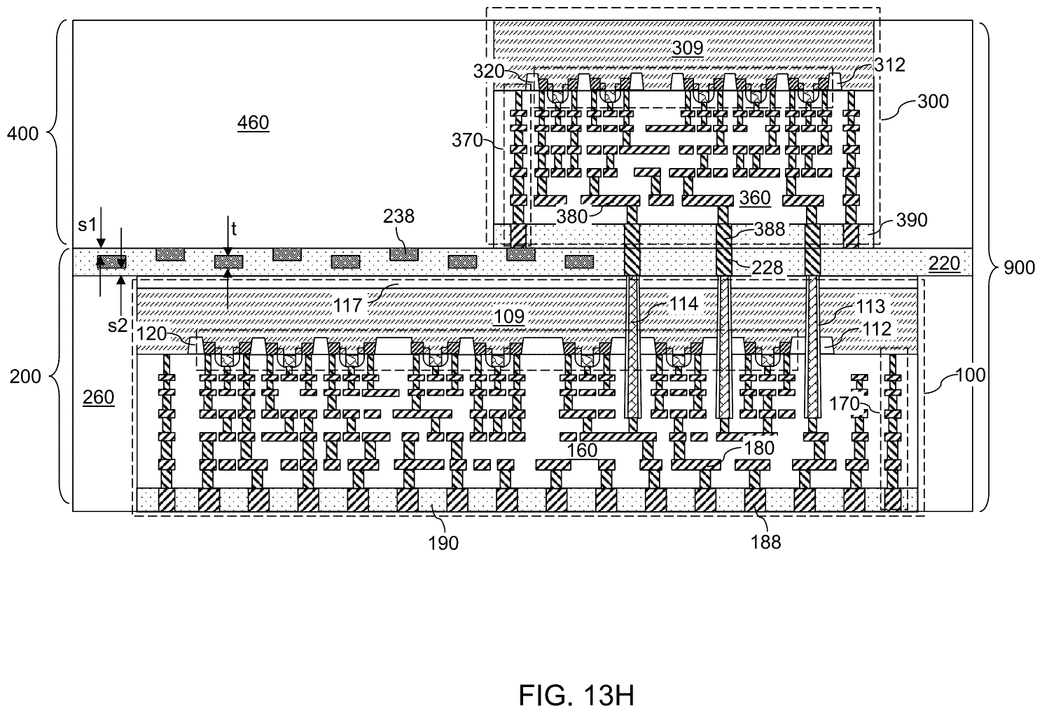

FIGS. 13A-13G are sequential vertical cross-sectional views of a region of a tenth configuration of the exemplary structure around at least one bonding-level dielectric layer 220 during the formation of dummy pads 238 and first bonding pads 228 according to an embodiment of the present disclosure. FIG. 13H is a vertical cross-sectional view of a composite die 900 having the tenth configuration according to an embodiment of the present disclosure. The processing sequence illustrated in FIGS. 13A-13G may be derived from the processing sequence described with reference to FIGS. 12A-12G by using a material that is the different from the material of the first bonding pads 228 to form the first subset of the dummy pads 238.

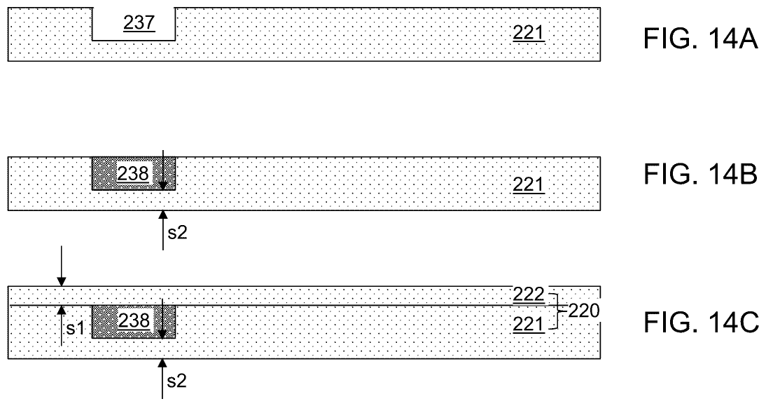

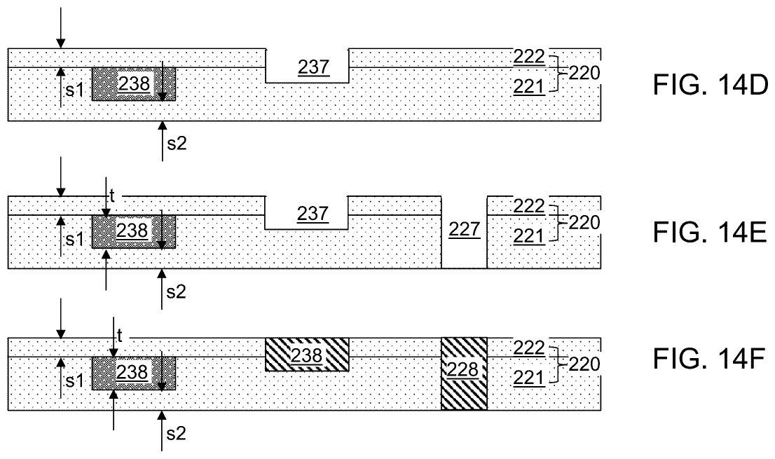

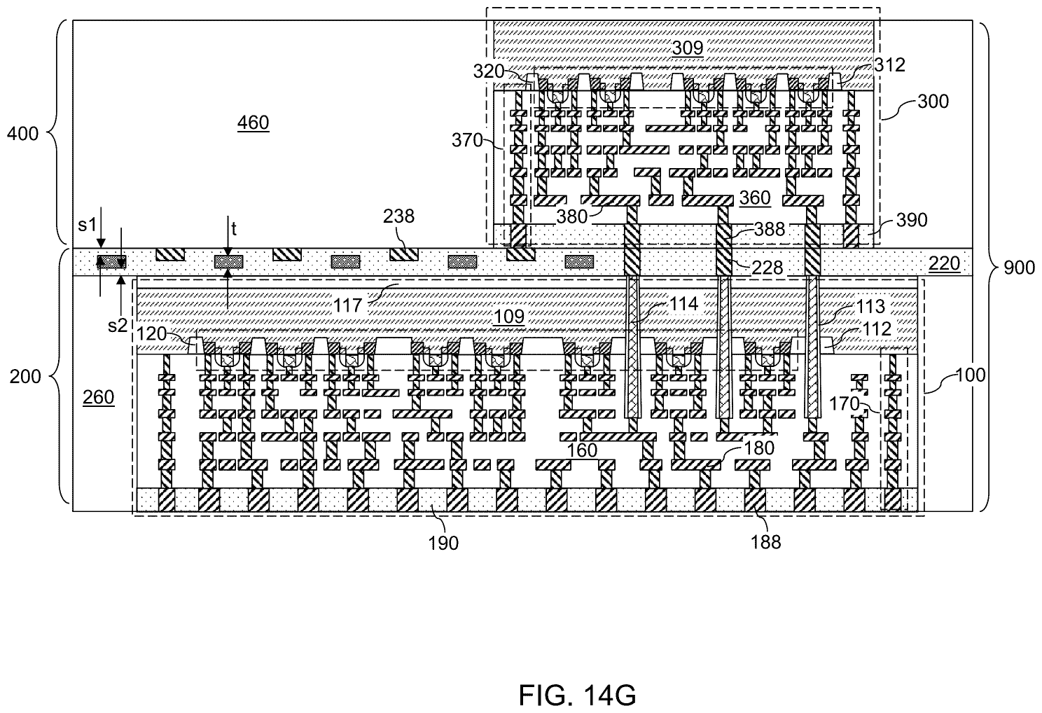

FIGS. 14A-14F are sequential vertical cross-sectional views of a region of an eleventh configuration of the exemplary structure around at least one bonding-level dielectric layer 220 during the formation of dummy pads 238 and first bonding pads 228 according to an embodiment of the present disclosure. FIG. 14G is a vertical cross-sectional view of a composite die 900 having the eleventh configuration according to an embodiment of the present disclosure. The processing sequence illustrated in FIGS. 14A-14F may be derived from the processing sequence described with reference to FIGS. 12A-12G by using a material that is the different from the material of the first bonding pads 228 to form the first subset of the dummy pads 238, and by using a same material as the material of the first bonding pads 228 to form the second subset of the dummy pads 238. In this embodiment, the second subset of the dummy-pad cavities 237 and the bonding-pad cavities 227 may be sequentially formed, in any order, and may be simultaneously filled with the second fill material for forming the first bonding pads 228. A planarization process may be performed to remove the second fill material from above the horizontal plane including the top surface of the upper bonding-level dielectric layer 222. Remaining portions of the second fill material comprise the second subset of the dummy pads 238 and the first bonding pads 228.

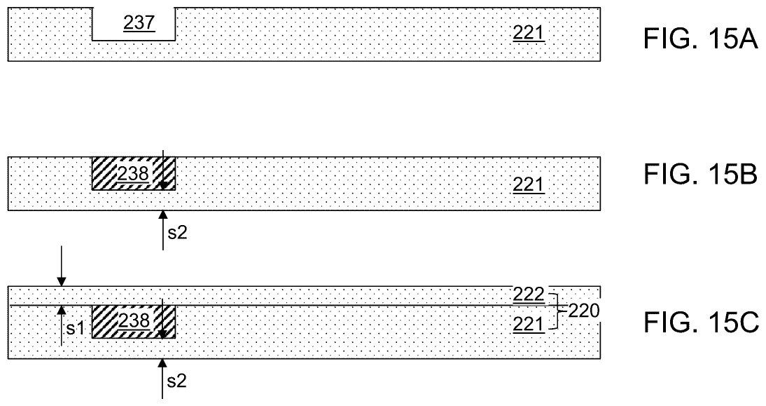

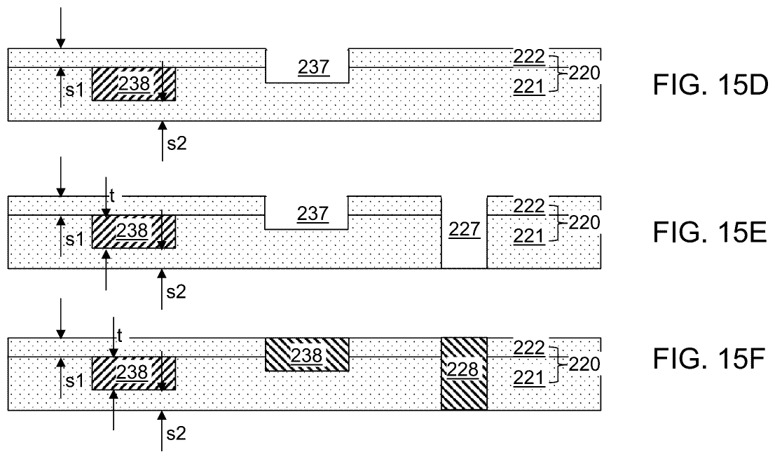

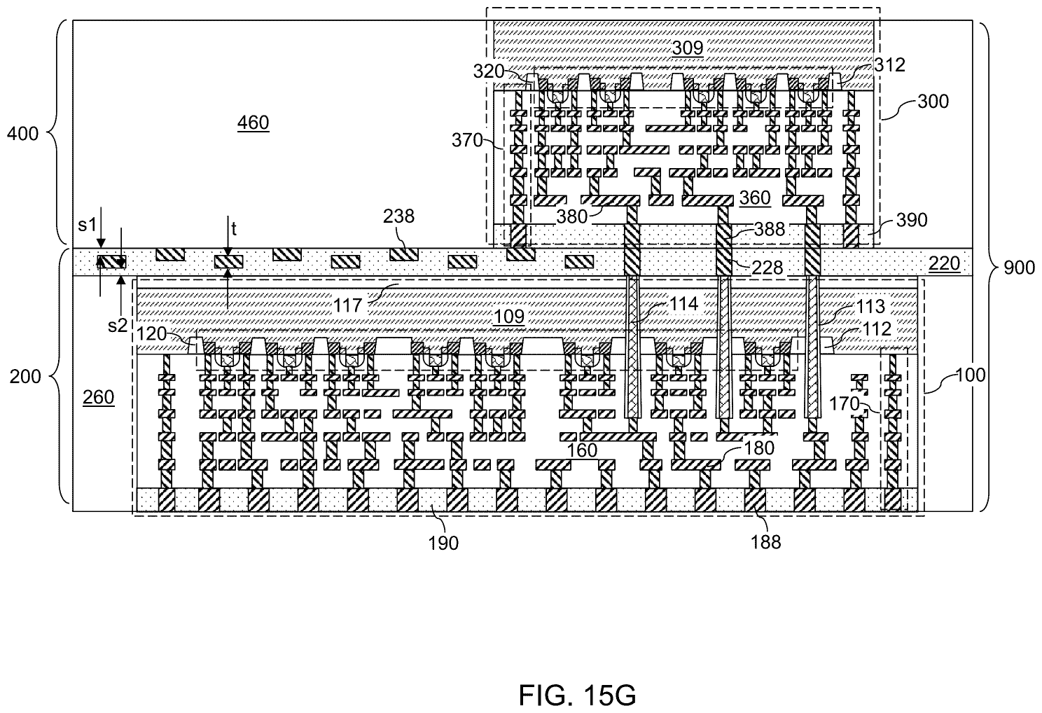

FIGS. 15A-15F are sequential vertical cross-sectional views of a region of a twelfth configuration of the exemplary structure around at least one bonding-level dielectric layer 220 during the formation of dummy pads 238 and first bonding pads 228 according to an embodiment of the present disclosure. FIG. 15G is a vertical cross-sectional view of a composite die 900 having the twelfth configuration according to an embodiment of the present disclosure. The processing sequence illustrated in FIGS. 15A-15F may be derived from the processing sequence described with reference to FIGS. 15A-15F by using a material that is the same as the material of the first bonding pads 228 to form the first subset of the dummy pads 238. Thus, the first subset of the dummy pads 238, the second subset of the dummy pads 238, and the first bonding pads 228 in FIGS. 15F and 15G may comprise a same metal or a same set of metallic materials (such as a combination of a thin metallic barrier liner material (such as TiN, TaN, WN, and/or MoN) and a copper fill material consisting essentially of copper.

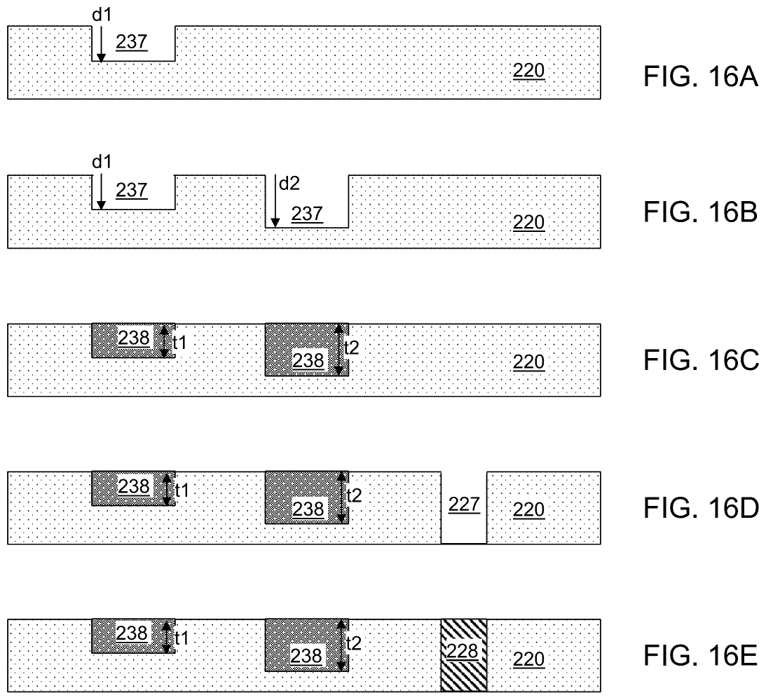

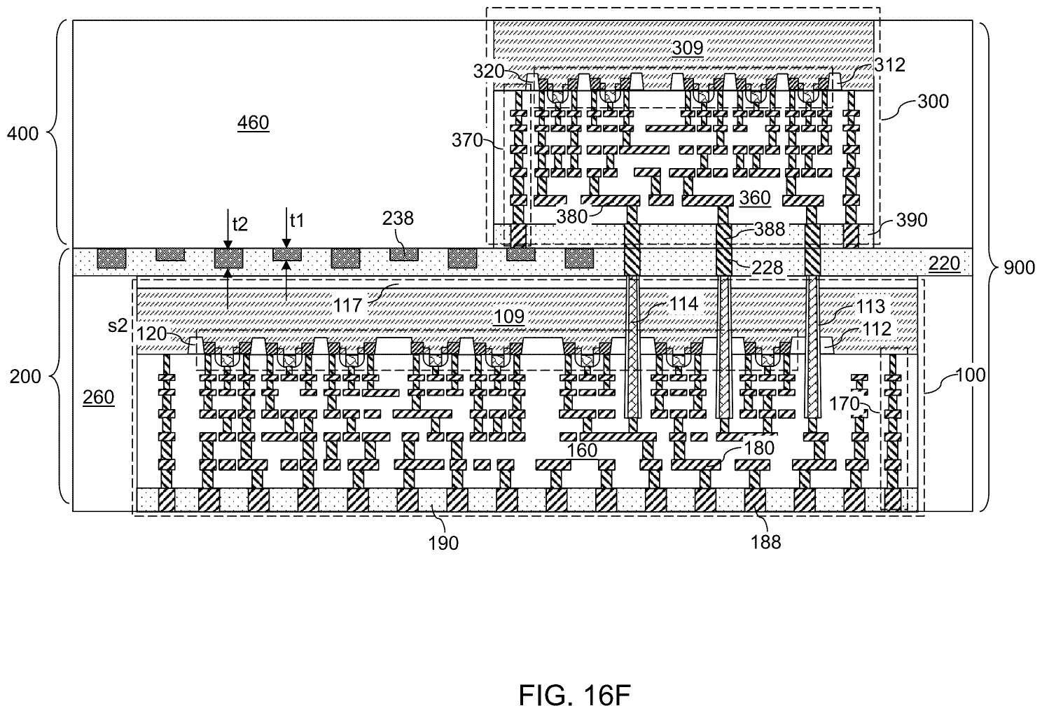

FIGS. 16A-16E are sequential vertical cross-sectional views of a region of a thirteenth configuration of the exemplary structure around at least one bonding-level dielectric layer 220 during the formation of dummy pads 238 and first bonding pads 228 according to an embodiment of the present disclosure. FIG. 16F is a vertical cross-sectional view of a composite die 900 having the thirteenth configuration according to an embodiment of the present disclosure. The processing sequence illustrated in FIGS. 16A-16E may be derived from the processing sequence described with reference to FIGS. 8A-8E by forming two sets of dummy-pad cavities 237 using two patterning sequences. For example, a first subset of the dummy-pad cavities 237 may be formed with a first depth d1, and a second subset of the dummy-pad cavities 237 may be formed with a second depth d2 that is different from the first depth d1. As a consequence, a first subset of the dummy pads 238 may have a first thickness t1, and a second subset of the dummy pads 238 may have a second thickness t2 that is different from the first thickness t1. The top surfaces of all dummy pads 238 may be coplanar with the top surface of the at least one bonding-level dielectric layer 220. Generally, the material of the first subset of the dummy pads 238 may be the same as, or may be different from, the material of the second subset of the dummy pads 238. The material of the first subset of the dummy pads 238 may be the same as, or may be different from, the material of the first bonding pads 228. The material of the second subset of the dummy pads 238 may be the same as, or may be different from, the material of the first bonding pads 228.

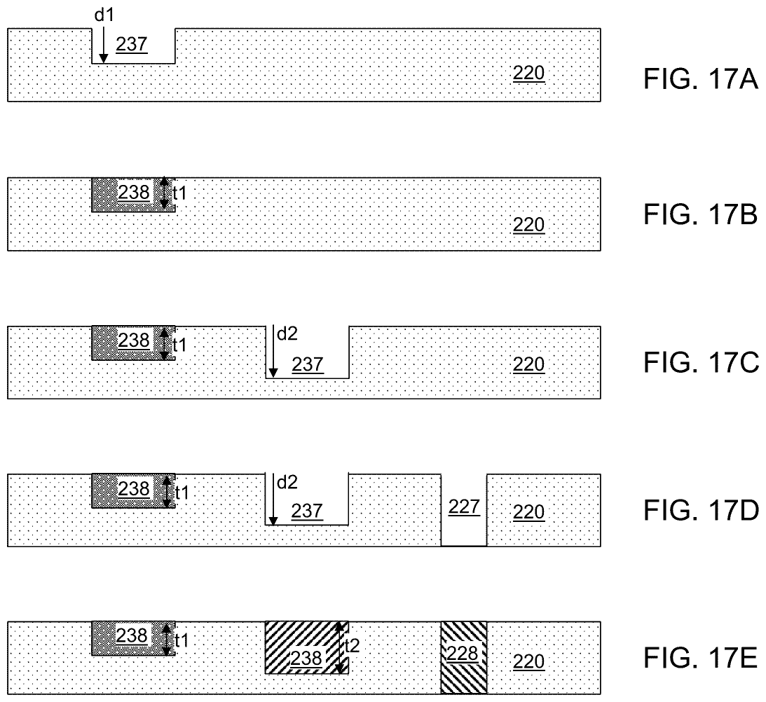

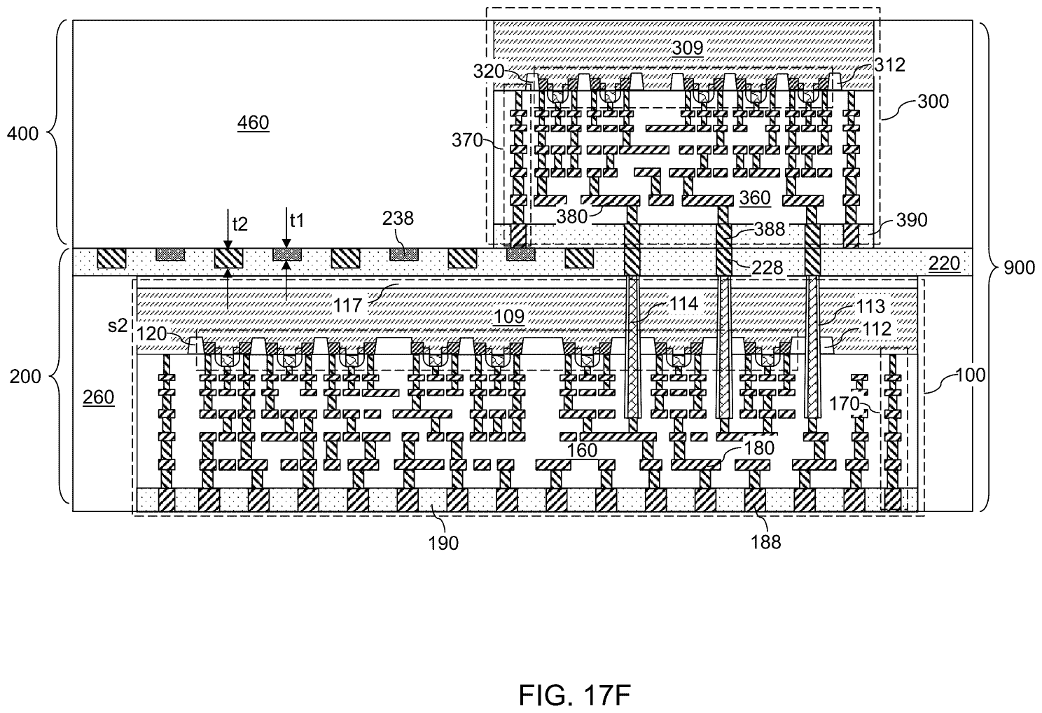

FIGS. 17A-17E are sequential vertical cross-sectional views of a region of a fourteenth configuration of the exemplary structure around at least one bonding-level dielectric layer 220 during the formation of dummy pads 238 and first bonding pads 228 according to an embodiment of the present disclosure. FIG. 17F is a vertical cross-sectional view of a composite die 900 having the fourteenth configuration according to an embodiment of the present disclosure. The processing sequence illustrated in FIGS. 17A-17E may be derived from the processing sequence described with reference to FIGS. 16A-16E by sequentially forming a first subset of the dummy pads 238 having a first thickness t1 and a second subset of the dummy pads 238 having a second thickness t2. Referring to FIG. 17A, a first subset of the dummy-pad cavities 237 having a first depth d1 may be formed. Referring to FIG. 17B, a first subset of the dummy pads 238 may be formed by depositing a fill material in the first subset of the dummy-pad cavities 237 and by performing a first planarization process. In the fourteenth configuration illustrated in FIGS. 17A-17E, the material of the first subset of the dummy pads 238 is different from the second fill material of the first bonding pads 228 that are subsequently performed. Referring to FIG. 17C, a second subset of the dummy-pad cavities 237 having a second depth d2 may be formed. The second depth d2 may be the same as, or may be different from, the first depth d1. Referring to FIG. 17D, bonding-pad cavities 227 may be formed by a combination of a lithographic patterning process and an anisotropic etch process. Referring to FIG. 17E, the second fill material may be deposited in the second subset of the dummy-pad cavities 237 and the bonding-pad cavities 227, and may be subsequently planarized to form a second subset of the dummy pads 238 and the first bonding pads 228. In the fourteenth configuration, the second subset of the dummy pads 238 and the first bonding pads 228 comprise a same metal or a same set of metallic materials (such as a combination of a thin metallic barrier liner material (such as TiN, TaN, WN, and/or MoN) and a copper fill material consisting essentially of copper. The first subset of the dummy pads 238 comprises a different material than the material of the second subset of the dummy pads 238 and the first bonding pads 228.

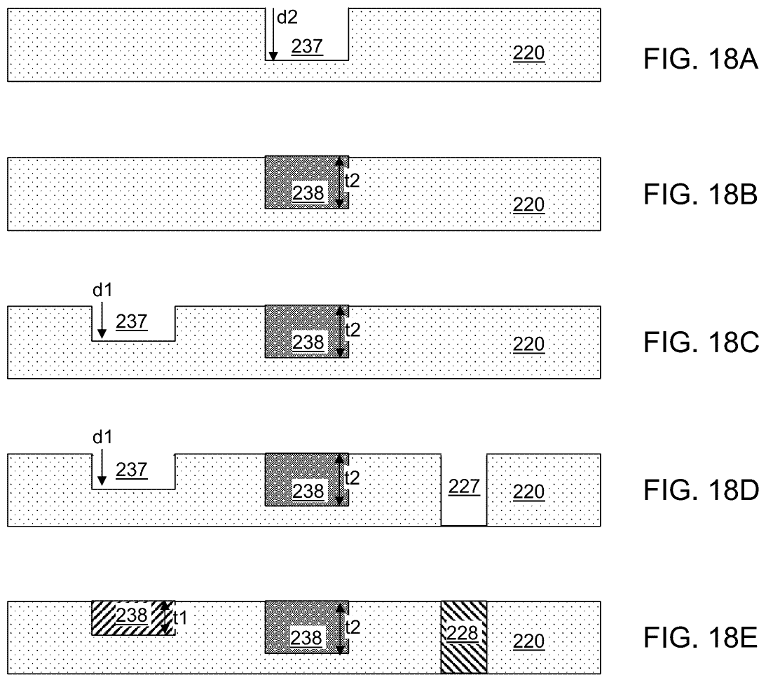

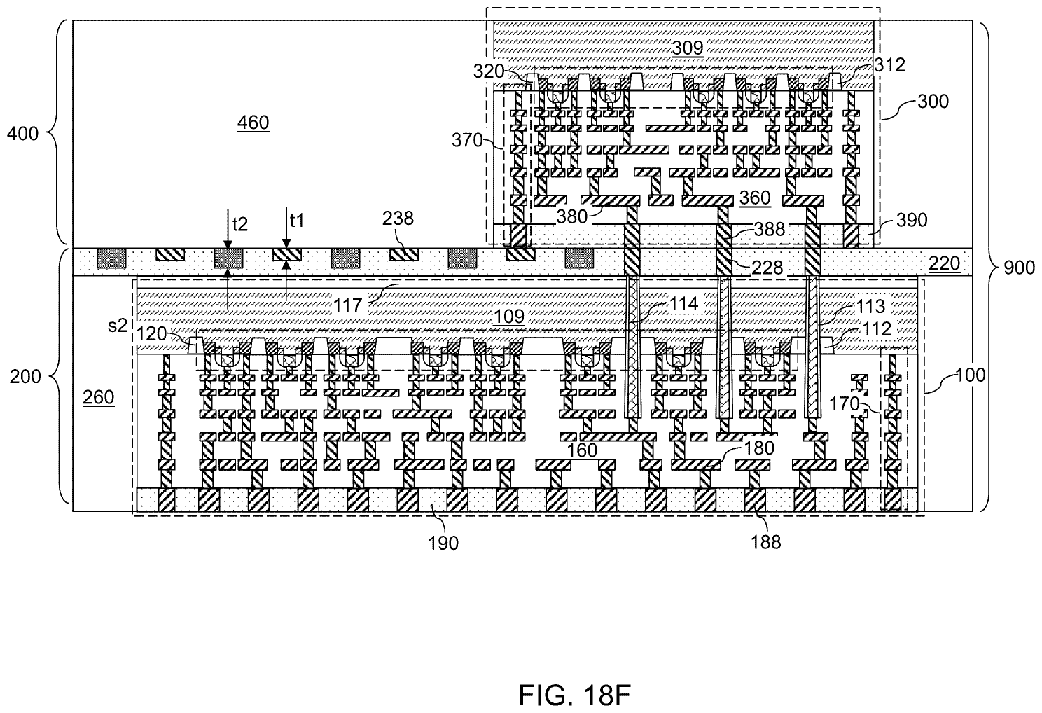

FIGS. 18A-18E are sequential vertical cross-sectional views of a region of a fifteenth configuration of the exemplary structure around at least one bonding-level dielectric layer 220 during the formation of dummy pads 238 and first bonding pads 228 according to an embodiment of the present disclosure. FIG. 18F is a vertical cross-sectional view of a composite die 900 having the fifteenth configuration according to an embodiment of the present disclosure. The processing sequence illustrated in FIGS. 18A-18E may be derived from the processing sequence described with reference to FIGS. 17A-17E by switching the pattern for the first subset of dummy-pad cavities 237 and the pattern for the second subset of the dummy-pad cavities 237. In the fifteenth configuration, the first subset of the dummy pads 238 (having the first thickness t1) and the first bonding pads 228 comprise a same metal or a same set of metallic materials (such as a combination of a thin metallic barrier liner material (such as TiN, TaN, WN, and/or MoN) and a copper fill material consisting essentially of copper. The second subset of the dummy pads 238 (having the second thickness t2) comprises a different material than the material of the second subset of the dummy pads 238 and the first bonding pads 228.

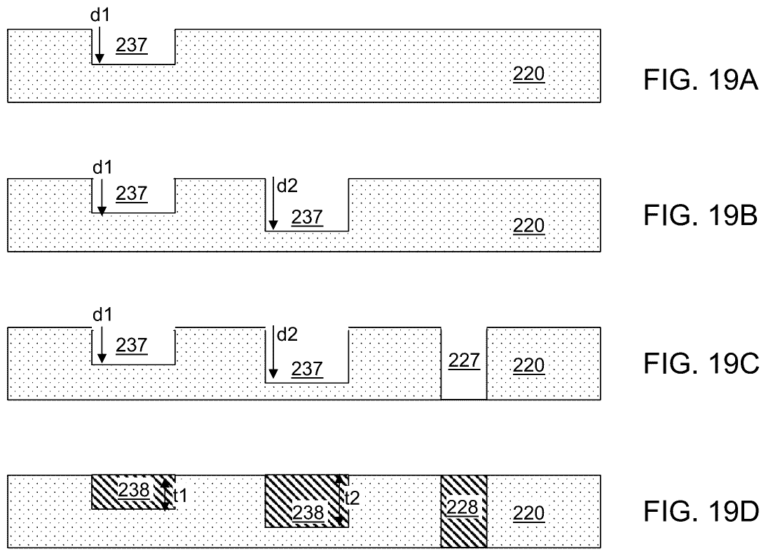

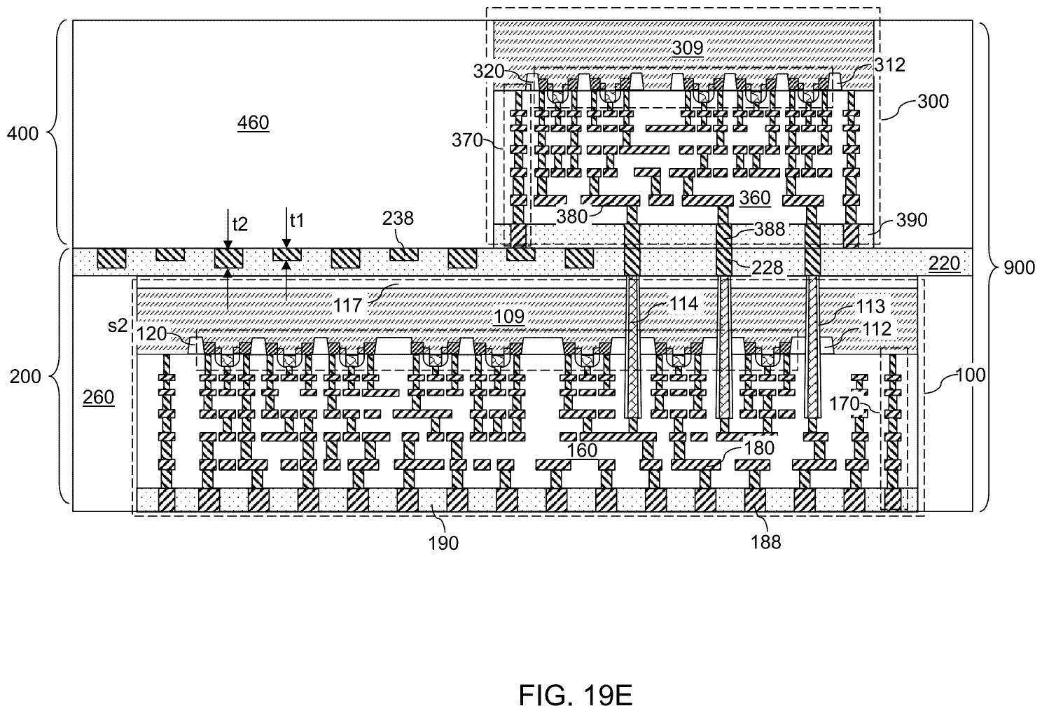

FIGS. 19A-19D are sequential vertical cross-sectional views of a region of a sixteenth configuration of the exemplary structure around at least one bonding-level dielectric layer 220 during the formation of dummy pads 238 and first bonding pads 228 according to an embodiment of the present disclosure. FIG. 19E is a vertical cross-sectional view of a composite die 900 having the sixteenth configuration according to an embodiment of the present disclosure. The processing sequence illustrated in FIGS. 19A-19D may be derived from the processing sequence described with reference to FIGS. 16A-16E by using the same metallic fill material for the first subset of the dummy-pad cavities 237, the second subset of the dummy-pad cavities 237, and the bonding-pad cavities 227. In this embodiment, the first subset of the dummy-pad cavities 237, the second subset of the dummy-pad cavities 237, and the bonding-pad cavities 227 having different depths may be formed in any order, and a metallic fill material may be deposited and planarized to form the first subset of the dummy pads 238 having the first thickness t1, the second subset of the dummy pads 238 having the second thickness t2, and the first bonding pads 228 having a greater thickness than the dummy pads 238. In the sixteenth configuration, the first subset of the dummy pads 238 (having the first thickness t1), the second subset of the dummy pads (having the second thickness t2), and the first bonding pads 228 comprise a same metal or a same set of metallic materials (such as a combination of a thin metallic barrier liner material (such as TiN, TaN, WN, and/or MoN) and a copper fill material consisting essentially of copper.

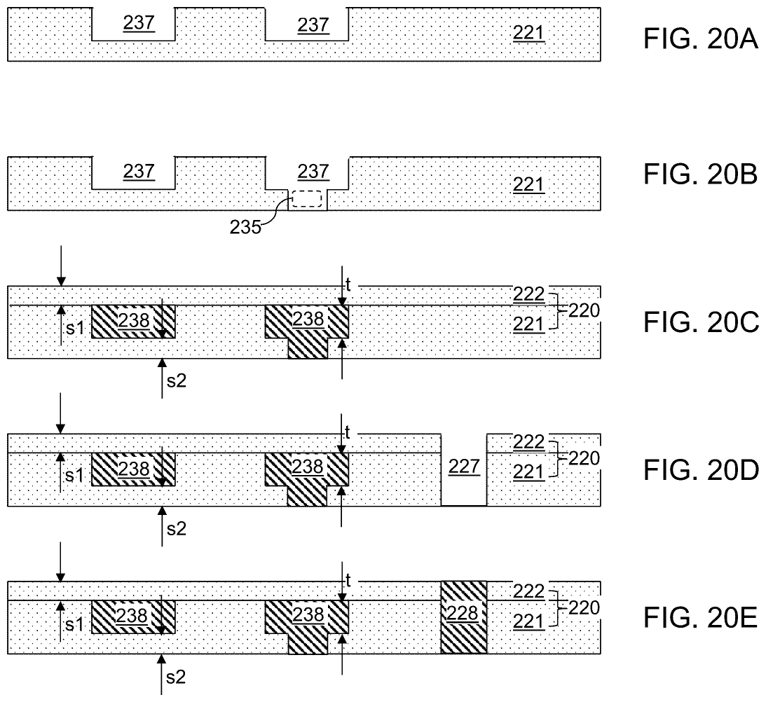

FIGS. 20A-20E are sequential vertical cross-sectional views of a region of a seventeenth configuration of the exemplary structure around at least one bonding-level dielectric layer 220 during the formation of dummy pads 238 and first bonding pads 228 according to an embodiment of the present disclosure. The processing sequence illustrated in FIGS. 20A-20E may be derived from the processing sequence described with reference to FIGS. 5A-5E by forming via cavities 235 underneath a subset of the dummy-pad cavities 237. Referring to FIG. 20, the dummy-pad cavities 237 formed in the lower bonding-level dielectric layer 221 may be the same as the dummy-pad cavities 237 described with reference to FIG. 5. Subsequently, a photoresist layer (not shown) may be applied over the lower bonding-level dielectric layer 221, and may be lithographically patterned to form openings within areas of a subset of the dummy-pad cavities 237. An anisotropic etch process may be performed to form via cavities 235 in areas of the dummy-pad cavities 237 that are not covered with the photoresist layer. The via cavities 235 may vertically extend to the bottom surface of the lower bonding-level dielectric layer 221, and a top surface of the first semiconductor die 100 may be physically exposed underneath each via cavity 235. The photoresist layer may be removed, for example, by ashing. Subsequently, the processing steps described with reference to FIGS. 5B-5E may be performed.

In the seventeenth configuration, at least one of the dummy pads 238 may have a bottom surface that is vertically offset from a first horizontal plane including bottom surfaces of the first bonding pads 228. At least an additional one of the dummy pads 238 comprises a via portion that extends to the first horizontal plane and contacts a surface of the first semiconductor die 100, which may be, generally speaking, a conductive surface, a semiconducting surface, or an insulating surface.

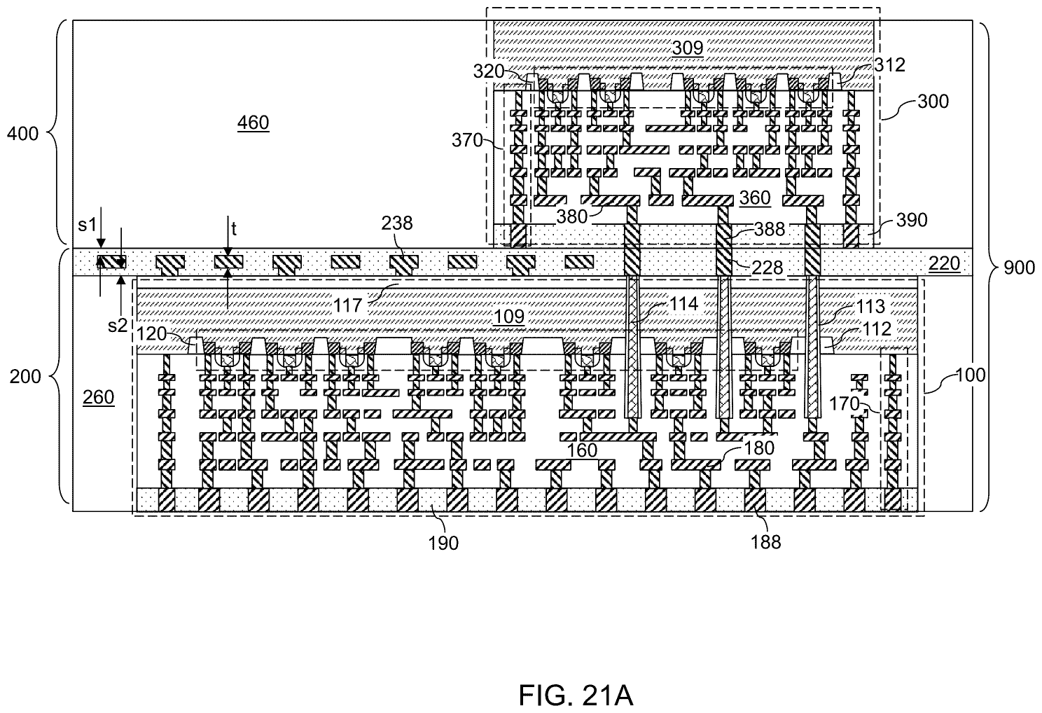

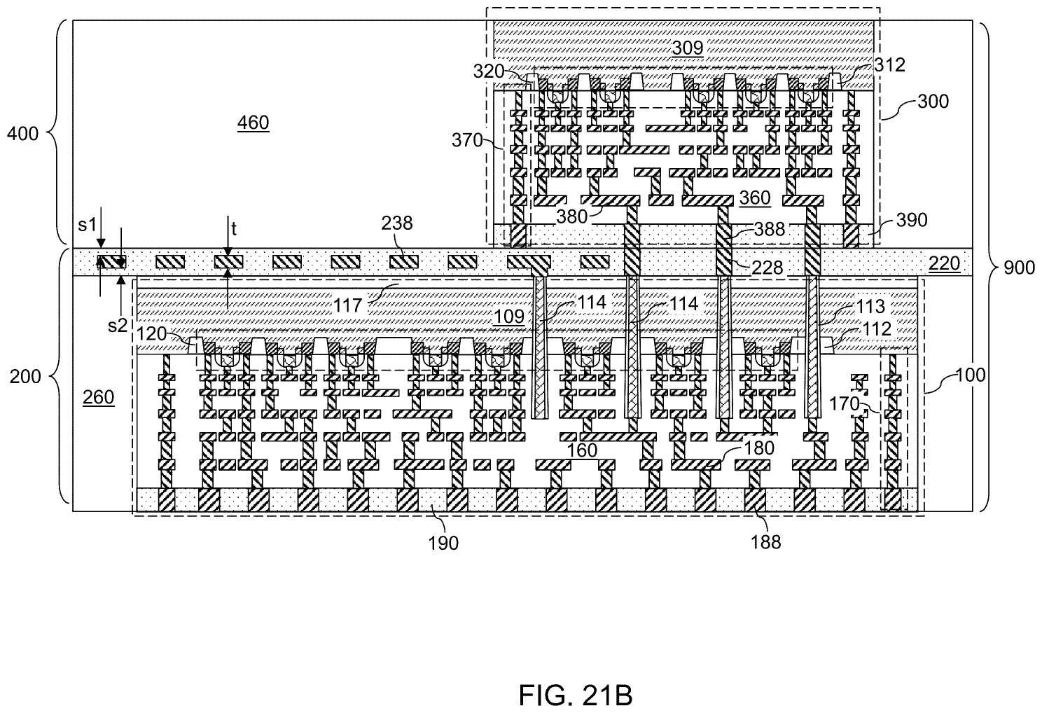

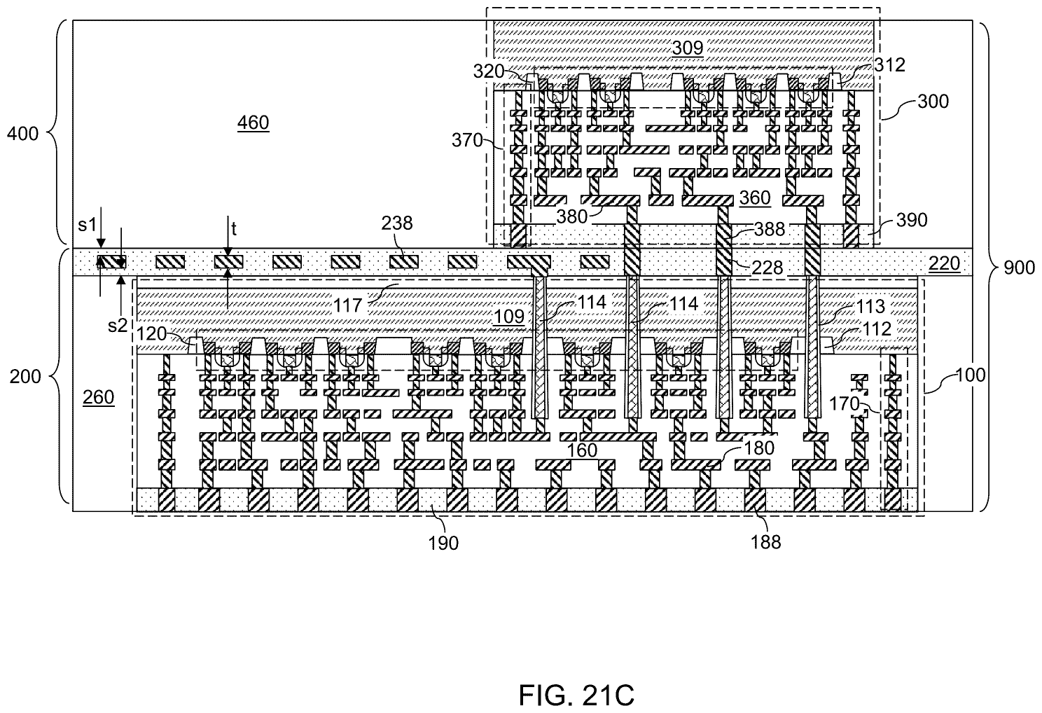

FIGS. 21A-21C are vertical cross-sectional views of various embodiments of a composite die 900 having the seventeenth configuration according to an embodiment of the present disclosure.

Referring to FIG. 21A, an embodiment of the seventeenth configuration is illustrated, in which a first subset of the dummy pads 238 comprises a respective via portion contacting an insulating surface of the first semiconductor die 100 (such as a surface of the first backside dielectric layer 117.

Referring to FIG. 21B, another embodiment of the seventeenth configuration is illustrated, in which a first subset of the dummy pads 238 comprises a respective via portion contacting a conductive structure within the first semiconductor die 100. In the illustrative example, the conductive structure may be a through-substrate via structure 114 that is electrically floating. Generally, at least an additional one of the dummy pads 238 comprises a via portion that extends to the first horizontal plane and contacts an additional conductive structure (such as a through-substrate via structure 114) within the first semiconductor die 100. In one embodiment, the additional one of the dummy pads 238 may be not in direct contact with any conductive structure (such as a through-substrate via structure 114) located on, or within, the second semiconductor die 300.

Referring to FIG. 21C, yet another embodiment of the seventeenth configuration is illustrated, in which a first subset of the dummy pads 238 comprises a respective via portion contacting a conductive structure within the first semiconductor die 100. In the illustrative example, the conductive structure may be a through-substrate via structure 114 that is electrically connected to a first semiconductor device 120. Generally, at least an additional one of the dummy pads 238 comprises a via portion that extends to the first horizontal plane and contacts an additional conductive structure (such as a through-substrate via structure 114) within the first semiconductor die 100. In one embodiment, the additional one of the dummy pads 238 may be not in direct contact with any conductive structure (such as a through-substrate via structure 114) located on, or within, the second semiconductor die 300.

Generally, a first subset of the dummy pads 238 may be electrically connected to a first semiconductor device 120 through a connecting conductive structure such as, but not limited to, a through-substrate via structure 114. The connecting conductive structure may comprise, for example, a redistribution wiring structure embedded within a redistribution dielectric layer, a metal interconnect structure such as a metal line or a metal via structure, or a metal pad structure. The first semiconductor device 120 to which the first subset of the dummy pads 238 may be electrically connected to may comprise a capacitor, a resistor, a heater, an electrical fuse, or any semiconductor device that may benefit from a connected heat sink. In some embodiments, the electrical connection of the first subset of the dummy pads 238 to a first semiconductor device 120 may increase the performance of the first semiconductor device 120 by increasing the resistance, the capacitance, or the thermal resilience (due to additional heat dissipation provided by the dummy pad 238).

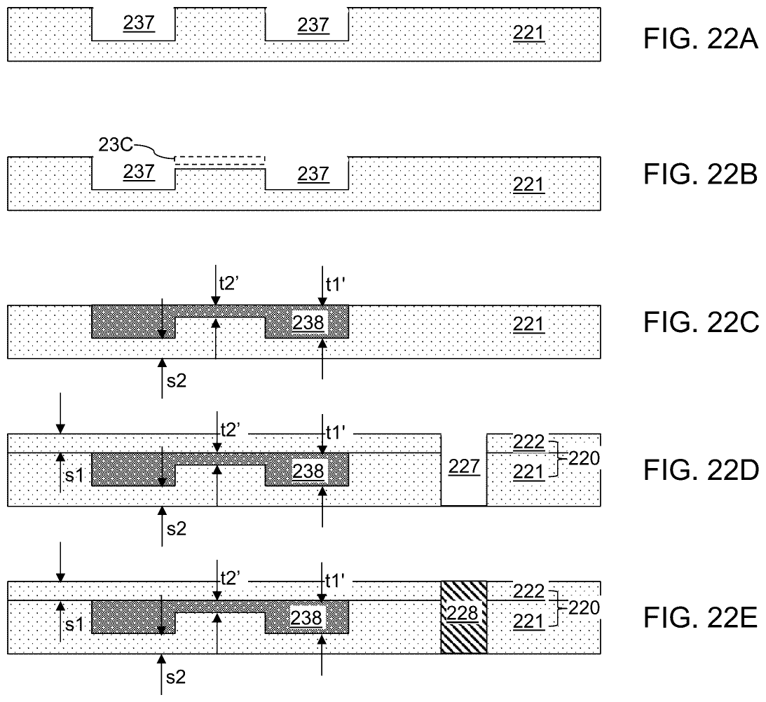

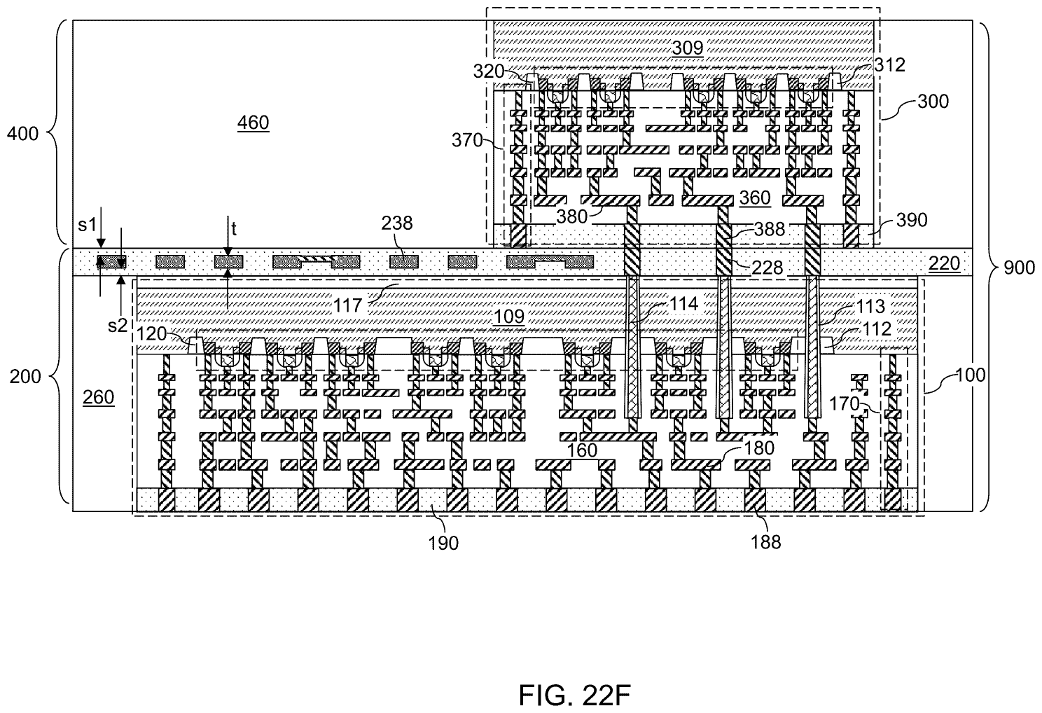

FIGS. 22A-22E are sequential vertical cross-sectional views of a region of an eighteenth configuration of the exemplary structure around at least one bonding-level dielectric layer 220 during the formation of dummy pads 238 and first bonding pads 228 according to an embodiment of the present disclosure. FIG. 22F is a vertical cross-sectional view of a composite die 900 having the eighteenth configuration according to an embodiment of the present disclosure. The sequence of processing steps illustrated in FIGS. 22A-22E may be derived from the sequence of processing steps described with reference to FIGS. 4A-4E by performing an additional processing step after formation of the dummy-pad cavities 237 that forms connection recesses 23C between selected neighboring pairs of dummy-pad cavities 237. For example, a photoresist layer (not shown) may be applied over the lower bonding-level dielectric layer 221 after formation of the dummy-pad cavities 237, and may be lithographically patterned to form opening between neighboring pairs of dummy-pad cavities 237. An etch process, such as an anisotropic etch process or an isotropic etch process, may be performed to form the connection recesses 23C. The photoresist layer may be subsequently removed, for example, by ashing. Subsequently, the processing steps described with reference to FGS. 4B-4E may be performed to form dummy pads 238.

A first subset of the dummy pads 238 may be formed with a plurality of main portions having a first thickness t1′ and at least one connecting portion having a second thickness t2′ that is less than the first thickness t1′. Generally, the dummy pads 238 may comprise the same material as, or may comprise a different material from, the material of the first bonding pads 228. In the eighteenth configuration, the material of the dummy pads 238 is different from the material of the first bonding pads 228. The connecting portions of the dummy pads 238 may deform, buckle, or be disconnected more easily than the main portions of the dummy pads 238, and thus, is capable of absorbing mechanical stress better than the main portions of the dummy pads 238.

Thus, the connecting portions of the dummy pads 238 may provide enhanced protection from deformation during, or after, formation of the second molding compound matrix.

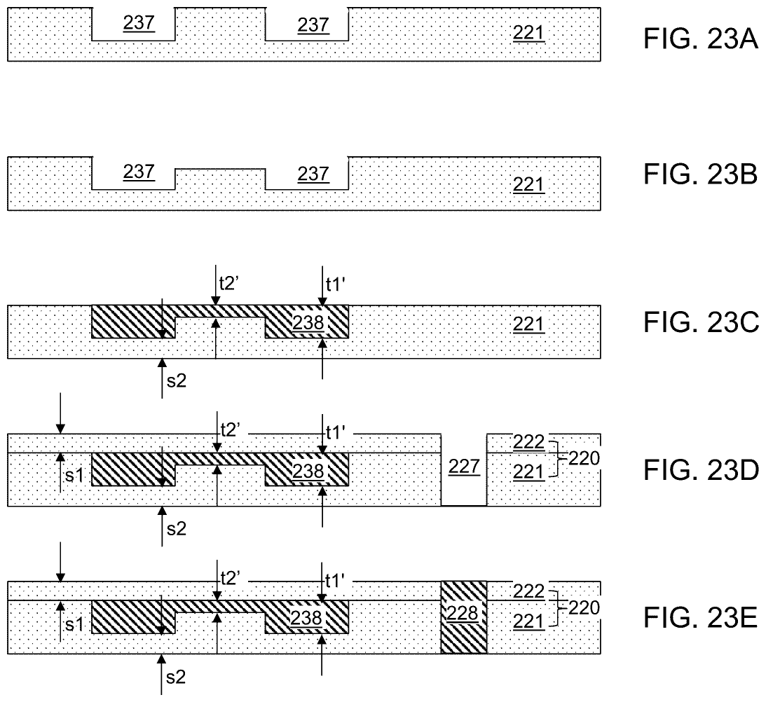

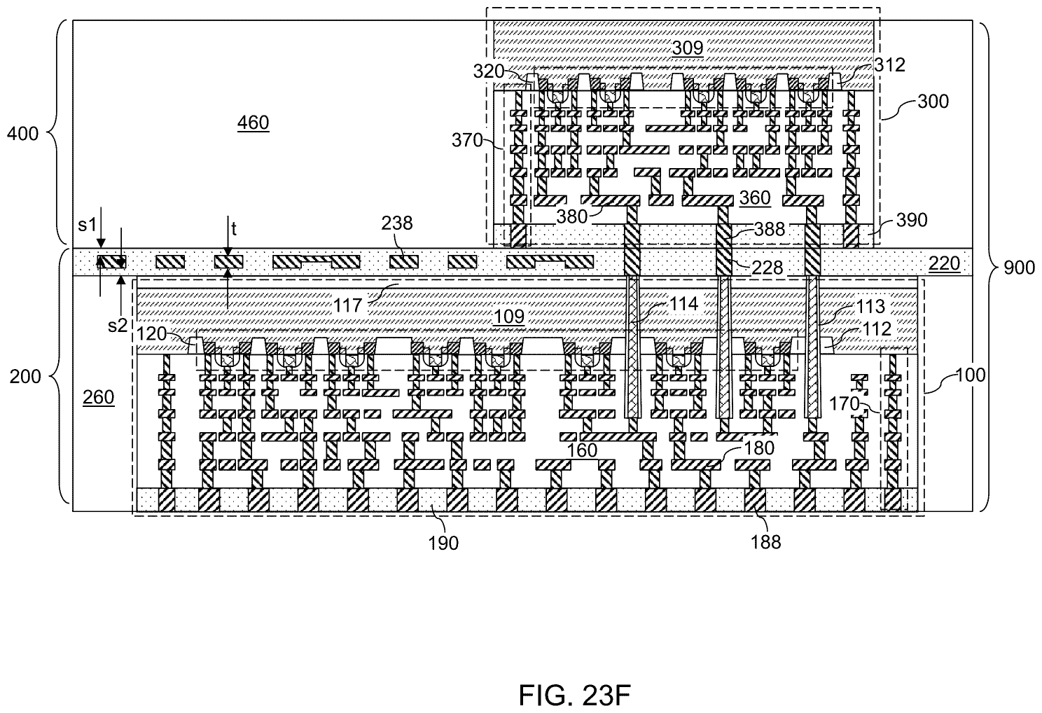

FIGS. 23A-23E are sequential vertical cross-sectional views of a region of a nineteenth configuration of the exemplary structure around at least one bonding-level dielectric layer 220 during the formation of dummy pads 238 and first bonding pads 228 according to an embodiment of the present disclosure. FIG. 23F is a vertical cross-sectional view of a composite die 900 having the nineteenth configuration according to an embodiment of the present disclosure. The sequence of processing steps illustrated in FIGS. 23A-23E may be derived from the sequence of processing steps described with reference to FIGS. 22A-22E by using the same material for the dummy pads 238 as the first bonding pads 228. Thus, the dummy pads 238 and the first bonding pads 228 may comprise a same metal or a same set of metallic materials (such as a combination of a thin metallic barrier liner material (such as TiN, TaN, WN, and/or MoN) and a copper fill material consisting essentially of copper.

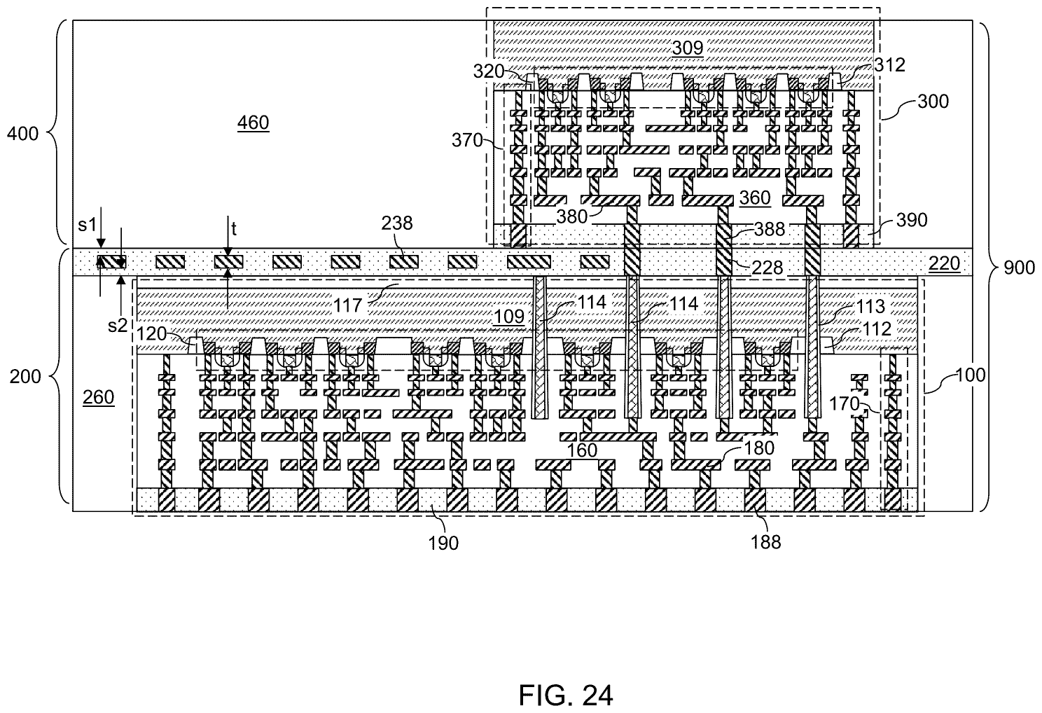

FIG. 24 is a vertical cross-sectional view of a composite die 900 having a twentieth configuration according to an embodiment of the present disclosure. The twentieth configuration of the composite die 900 may be derived from any of the previously described configurations by forming at least one conductive structure that extends through the first semiconductor die 100 to a first horizontal plane including the bottom surfaces of the first bonding pads 228. For example, the at least one conductive structure may comprise a through-substrate via structure 114. Such conductive structures may be advantageously used to electrically and/or thermally couple with a subset of the dummy pads 238 to enhance thermal dissipation of the heat generated from the first semiconductor devices 120. While a direct contact between a conductive structure and a dummy pad 238 is preferred, such a direct contact is not required to provide the function of heat dissipation.

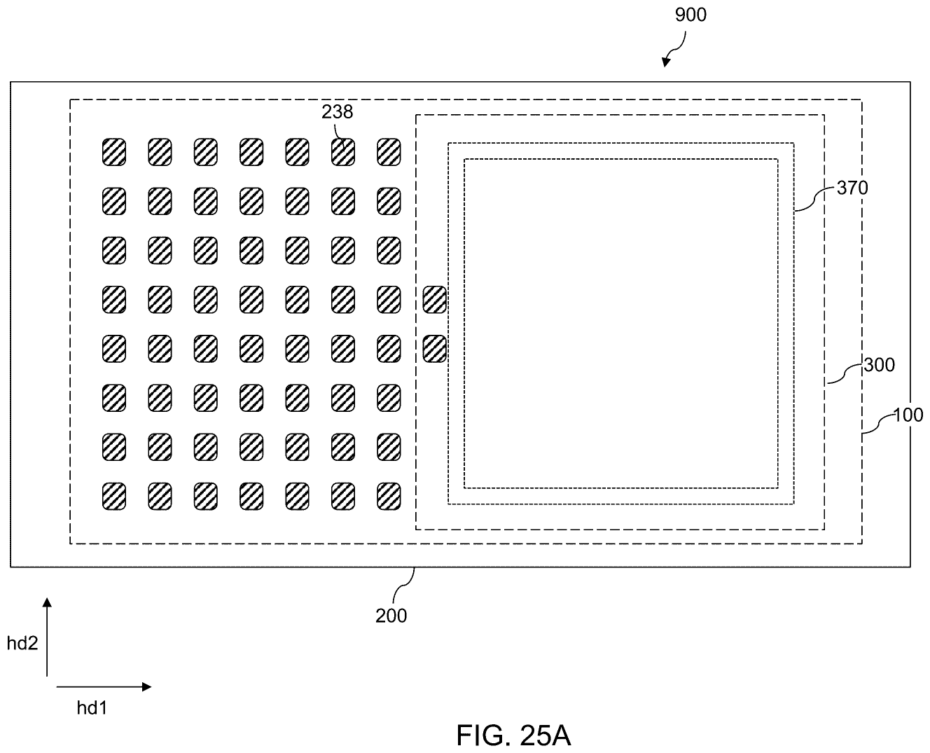

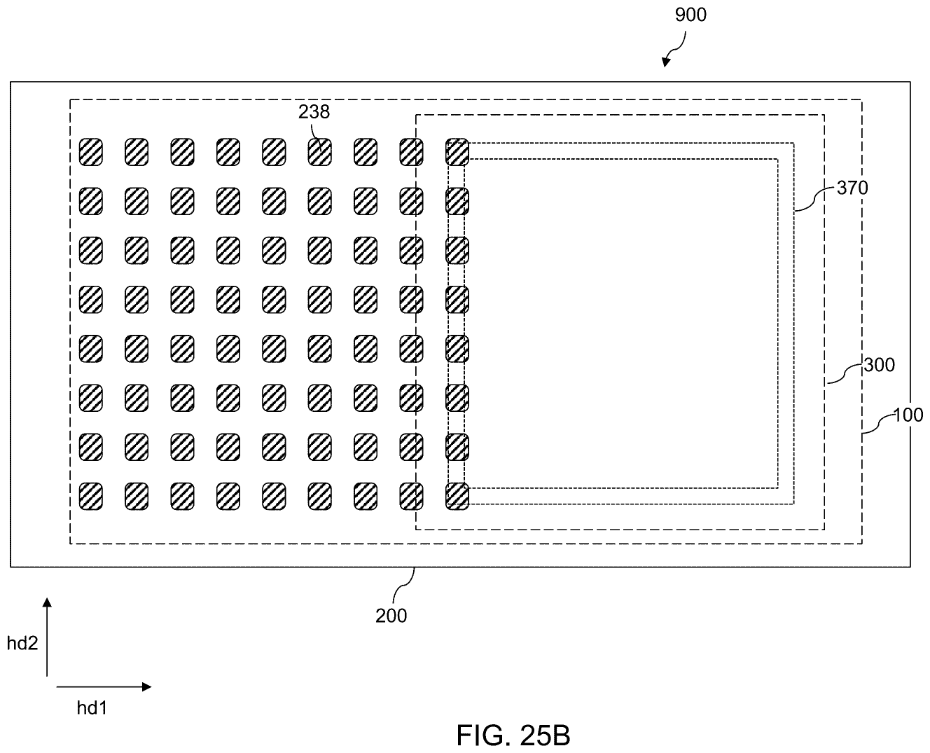

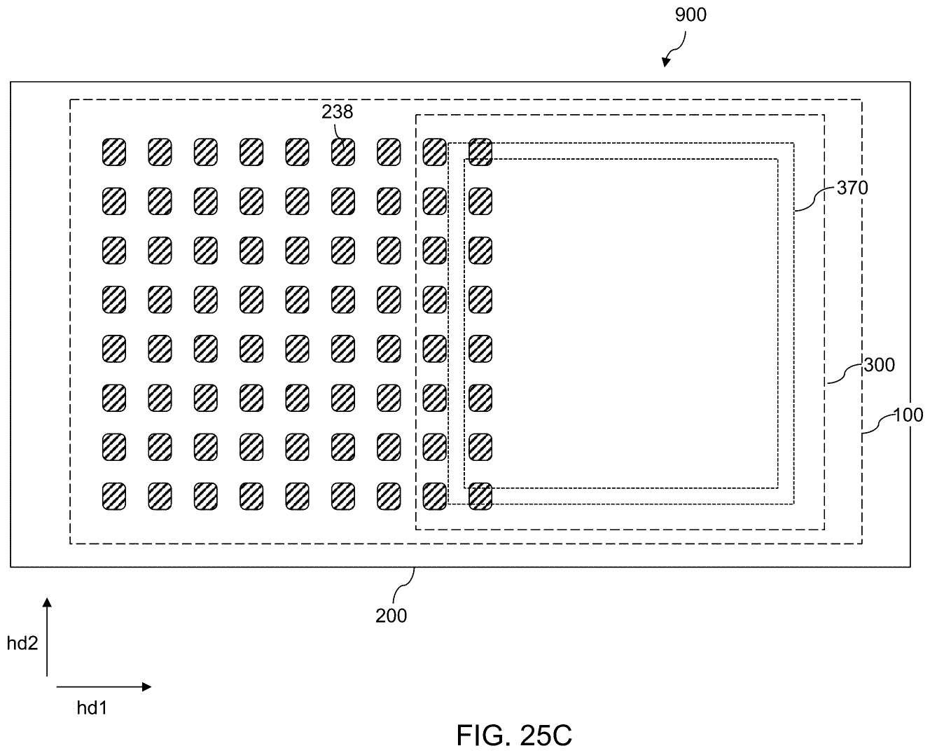

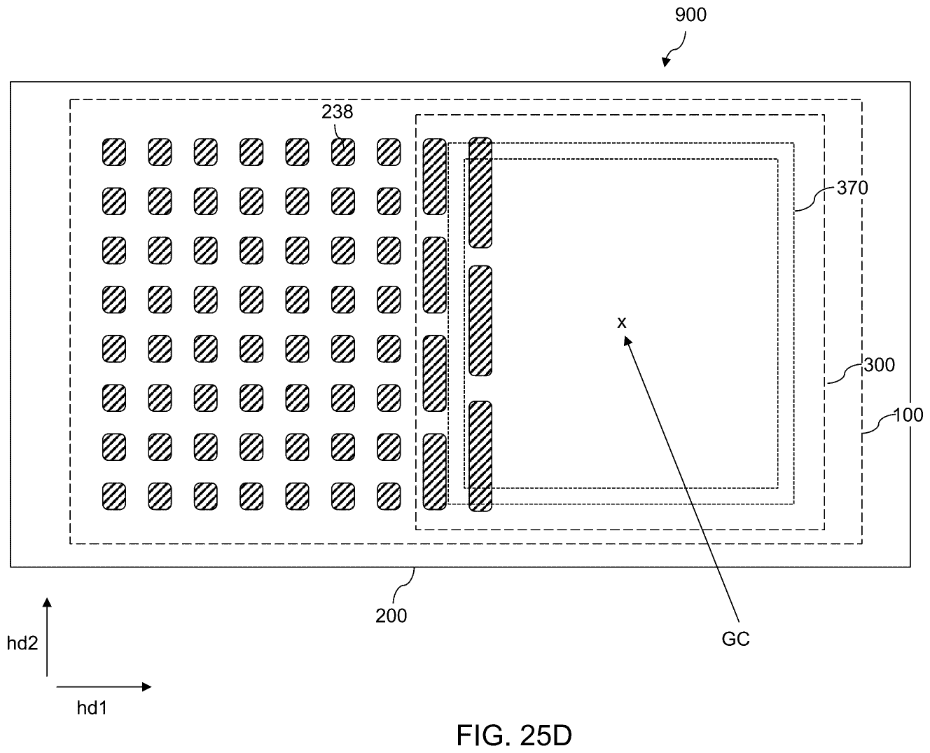

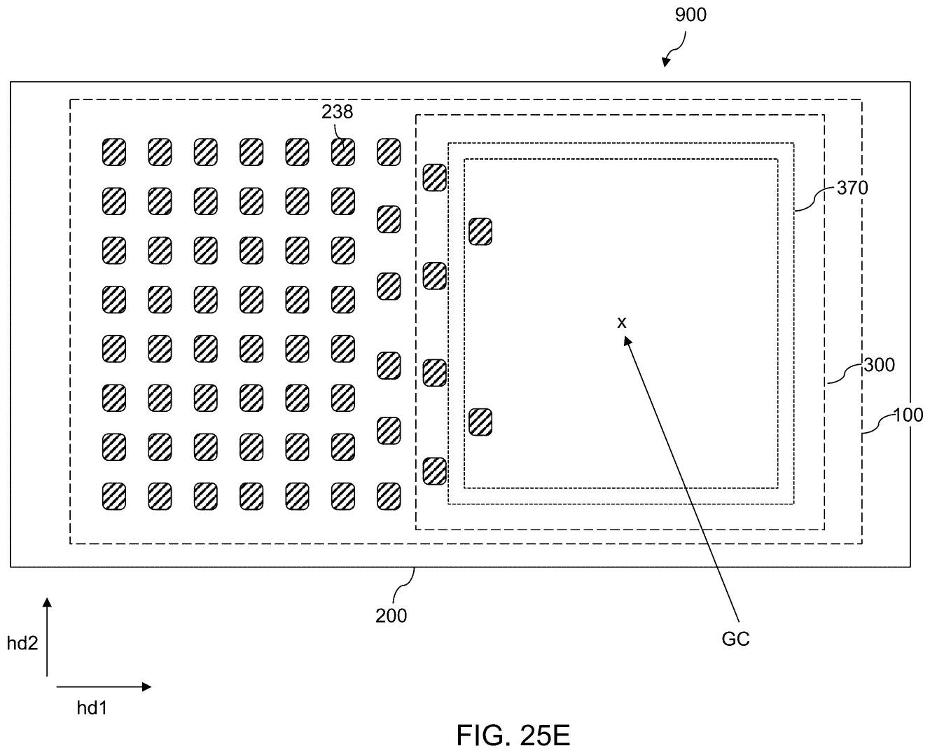

FIGS. 25A-25E are see-through top-down views of a composite die 900 having various configurations according to an embodiment of the present disclosure. Generally, the layout of the dummy pads 238 may be modified in order to minimize the effect of stress that is generated during formation of the second molding compound matrix 460. Thus, the number, the shapes, the size, and the pattern density of the dummy pads 238 may be selected in a manner that minimizes effect of the mechanical stress generated during formation of the second molding compound matrix 460, and to avoid formation of cracks within the second molding compound matrix.

FIG. 25A illustrates an example in which the density of the dummy pads 238 within the area of the second semiconductor die 300 in a plan view is less than the density of the dummy pads 238 outside the area of the second semiconductor die 300 in the plan view.

FIG. 25B illustrates an example in which the locations of the dummy pads 238 are selected such that overlap between the area enclosed by the edge seal ring structure 370 and the dummy pads 238 is non-zero, but at a minimal level, by positioning a most proximal row of dummy pads 238 directly underneath a straight segment of the edge seal ring structure 370 that is parallel to a sidewall of the second semiconductor die 300.

FIG. 25C illustrates an example in which the areal overlap between the edge seal ring structure 370 and the dummy pads 238 is minimized by positioning a most proximal row of dummy pads 238 inside the area enclosed by inner sidewalls of the edge seal ring structure 370.

FIG. 25D illustrates an example in which the size of the dummy pads 238 is modulated as a function of proximity to a geometrical center of the second semiconductor die 300 in a plan view in order to minimize the effect of mechanical stress generated during formation of the second molding compound matrix 460.

FIG. 25E illustrates an example in which the pattern density of the dummy pads 238 is modulated as a function of proximity to a geometrical center of the second semiconductor die 300 in a plan view in order to minimize the effect of mechanical stress generated during formation of the second molding compound matrix 460.

Referring collectively to FIGS. 3 and 25A-25E, the second semiconductor die 300 may comprise an edge seal ring structure 370 that extends continuously along all sidewalls of the second semiconductor die 300. In one embodiment, at least one dummy pad 238 within a first subset of the dummy pads 238 overlaps with the edge seal ring structure 370 in the plan view. Additionally or alternatively, at least one dummy pad 238 within a first subset of the dummy pads 238 is at least partly within an area enclosed by the edge seal ring structure 370 in the plan view. Additionally or alternatively, at least one dummy pad 238 within a first subset of the dummy pads 238 is located at least partly within a frame-shaped area located between an outer periphery of the edge seal ring structure 370 and sidewalls of the second semiconductor die 300 in the plan view.

Referring collectively to FIGS. 1-25E and according to various embodiments of the present disclosure, a semiconductor structure comprises: a molding compound 260 laterally surrounding a first semiconductor die 100 and having a top surface that is coplanar with a top dielectric surface of the first semiconductor die 100; at least one bonding-level dielectric layer 220 having formed therein first bonding pads 228 and dummy pads 238 and located over the first semiconductor die 100 and the molding compound 260, wherein each of the first bonding pads 228 is electrically connected to a respective conductive structure (such as a through-substrate via structure 114) within the first semiconductor die 100; and a second semiconductor die 300 including second bonding pads 388 that are bonded to the first bonding pads 228 by metal-to-metal bonding, wherein a first subset of the dummy pads 238 has an areal overlap in a plan view with the second semiconductor die 300.

In one embodiment, the second semiconductor die 300 comprises an edge seal ring structure 370 that extends continuously along all sidewalls of the second semiconductor die 300; and at least one dummy pad 238 within the first subset of the dummy pads 238 overlaps with the edge seal ring structure 370 in the plan view. In one embodiment, one of the dummy pads 238 has a different material composition than the first bonding pads 228. In one embodiment, one of the dummy pads 238 has a top surface that is vertically offset from a horizontal plane including top surfaces of the first bonding pads 228.

In one embodiment, one of the dummy pads 238 has a bottom surface that is vertically offset from a first horizontal plane including bottom surfaces of the first bonding pads 228. In one embodiment, an additional one of the dummy pads 238 comprises a via portion that extends to the first horizontal plane and contacts an additional conductive structure (such as a through-substrate via structure 114) within the first semiconductor die 100. In one embodiment, the additional one of the dummy pads 238 may, or may not be, in direct contact with any conductive structure (such as a through-substrate via structure 114) located on, or within, the second semiconductor die 300.

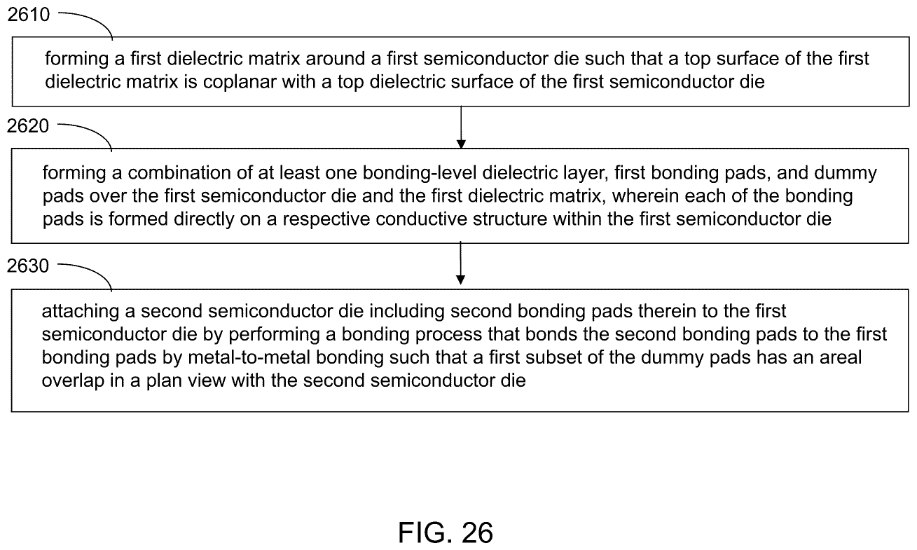

FIG. 26 is a first flowchart illustrating steps for forming a semiconductor structure according to an embodiment of the present disclosure.

Referring to step 2610 and FIGS. 1, 2A, and 2B, a first molding compound matrix 260 may be formed around a first semiconductor die 100 such that a top surface of the first molding compound matrix 260 is coplanar with a top dielectric surface of the first semiconductor die 100.

Referring to step 2620 and FIG. 2C and 3-25E, a combination of at least one bonding-level dielectric layer 220, first bonding pads 228, and dummy pads 238 may be formed over the first semiconductor die 100 and the first molding compound matrix 260. Each of the first bonding pads 228 is formed directly on a respective conductive structure (such as a through-substrate via structure 114) within the first semiconductor die 100.

Referring to step 2630 and FIGS. 2D-2F, a second semiconductor die 300 including second bonding pads 388 therein may be attached to the first semiconductor die 100 by performing a bonding process that bonds the second bonding pads 388 to the first bonding pads 228 by metal-to-metal bonding such that a first subset of the dummy pads 238 has an areal overlap in a plan view with the second semiconductor die 300.

In one embodiment, the second semiconductor die 300 may include an edge seal ring structure 370 that extends continuously along all sidewalls of the second semiconductor die 300; and the embodiment method comprises positioning the second semiconductor die 300 over the first semiconductor die 100 during the bonding process such that at least one dummy pad 238 within the first subset of the dummy pads 238 overlaps with the edge seal ring structure 370 in the plan view. In one embodiment, the second semiconductor die 300 may include an edge seal ring structure 370 that extends continuously along all sidewalls of the second semiconductor die 300; and the method comprises positioning the second semiconductor die 300 over the first semiconductor die 100 during the bonding process such that at least one dummy pad 238 within the first subset of the dummy pads 238 is at least partly within an area enclosed by the edge seal ring structure 370 in the plan view. In one embodiment, the second semiconductor die 300 may include an edge seal ring structure 370 that extends continuously along all sidewalls of the second semiconductor die 300; and the embodiment method comprises positioning the second semiconductor die 300 over the first semiconductor die 100 during the bonding process such that at least one dummy pad 238 within the first subset of the dummy pads 238 is located at least partly within a frame-shaped area located between an outer periphery of the edge seal ring structure 370 and sidewalls of the second semiconductor die 300 in the plan view. In one embodiment, the dummy pads 238 may be formed by depositing and patterning a first fill material within a first subset of the at least one bonding-level dielectric layer 220; and the first bonding pads 228 may be formed by depositing and patterning a second fill material within the at least one bonding-level dielectric layer 220 such that each of the first bonding pads 228 vertically extend from a bottommost surface of the at least one bonding-level dielectric layer 220 to a topmost surface of the at least one bonding-level dielectric layer 220.

In one embodiment, the first fill material is deposited by a first deposition process and is planarized by a first planarization process to form the dummy pads 238; and the second fill material is deposited by a second deposition process and is planarized by a second planarization process to form the first bonding pads 228, the second deposition process being different from the first deposition process. In one embodiment, the method further includes: depositing a second subset of the at least one bonding-level dielectric layer 220 over the dummy pads 238; and forming bonding-pad cavities 227 through the second subset and through the first subset, wherein the first bonding pads 228 are formed in the bonding-pad cavities 227.

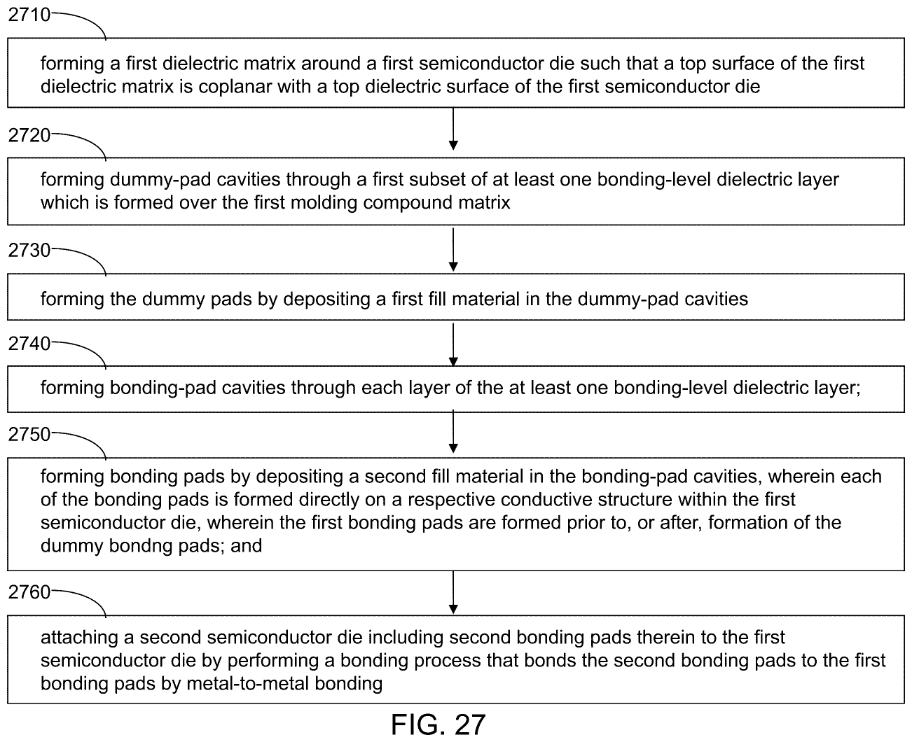

FIG. 27 is a second flowchart illustrating steps for forming a semiconductor structure according to an embodiment of the present disclosure.

Referring to step 2710 and FIGS. 1, 2A, and 2B, a first molding compound matrix 260 may be formed around a first semiconductor die 100 such that a top surface of the first molding compound matrix 260 is coplanar with a top dielectric surface of the first semiconductor die 100.

Referring to step 2720 and FIGS. 4A, 5A, 6A, 7A, 8A, 8B, 9A, 9B, 10A, 10B, 11A, 11B, 12A, 12C, 12D, 13A, 13C, 13D, 14A, 14C, 14D, 15A, 15D, 16A, 16B, 17A, 17C, 18A, 18C, 19A, 19B, 20A, 20B, 22A, 22B, 23A, and 23B, dummy-pad cavities 237 may be formed through a first subset of at least one bonding-level dielectric layer 220.

Referring to step 2730 and FIGS. 4B, 5B, 6B, 7B, 8C, 9D, 10C, 11C, 12B, 12E, 13B, 13E, 14B, 14F, 15B, 15F, 16C, 17B, 17F, 18B, 18E, 19D, 20C, 20C, 22C, and 23C, dummy pads 238 may be formed by depositing a first fill material in the dummy-pad cavities 237.

Referring to step 2740 and FIGS. 4C, 4D, 5C, 5D, 6C, 6D, 7C, 7D, 8D, 9C, 10D, 11A, 11B, 12F, 13F, 14E, 15D, 16D, 17D, 18D, 19C, 20D, 22D, and 23D, bonding-pad cavities 227 may be formed through each layer of the at least one bonding-level dielectric layer 220.

Referring to step 2750 and FIGS. 2C, 4E, 5E, 6E, 7E, 8E, 9D, 10E, 11C, 12G, 13G, 14F, 15F, 16E, 17E, 18E, 19D, 20E, 22E, and 23E, first bonding pads 228 may be formed by depositing a second fill material in the bonding-pad cavities 227, wherein each of the first bonding pads 228 is formed directly on a respective conductive structure (such as a through-substrate via structure 114) within the first semiconductor die 100.

Referring to step 2760 and FIGS. 2D-2F, 3, 5F, 6F, 7F, 8F, 9E, 10F, 11D, 12H, 13H, 14G, 15G, 16F, 17F, 18F, 19E, 21A-21C, 22F, 23F, 24, and 25A-25D, a second semiconductor die 300 including second bonding pads 388 therein may be attached to the first semiconductor die 100 by performing a bonding process that bonds the second bonding pads 388 to the first bonding pads 228 by metal-to-metal bonding such that a first subset of the dummy pads 238 has an areal overlap in a plan view with the second semiconductor die 300.

In one embodiment, the dummy-pad cavities 237 may be formed with a first depth; and the bonding-pad cavities 227 are formed with a second depth that is greater than the first depth. In one embodiment, the method may further include performing a first planarization process that removes excess portions of the first fill material from above a horizontal plane including a topmost surface of the first subset of at least one bonding-level dielectric layer 220. In one embodiment, the bonding-pad cavities may be formed after performing the first planarization process. In one embodiment, the method may include performing a second planarization process that removes excess portions of the second fill material from above a horizontal plane including a topmost surface of the at least one bonding-level dielectric layer 220, wherein the first bonding pads 228 comprise remaining portions of the second fill material after the second planarization process. In one embodiment, the first fill material has a first material composition, and is deposited by performing a first deposition process; and the second fill material has a second material composition that is different from the first material composition, and is deposited by performing a second deposition process that is different from the first deposition process. In one embodiment, the first subset of the at least one bonding-level dielectric layer 220 may be less than an entirety of the at least one bonding-level dielectric layer 220; and the method includes depositing a second subset of the at least one bonding-level dielectric layer 220 over the first subset of the at least one bonding-level dielectric layer 220.

Embodiments of the present disclosure provide metal-to-metal bonding with enhanced stress relief around the bonding areas through placement of dummy pads 238 under and around peripheral regions of an upper semiconductor die, i.e., the second semiconductor die 300. The dummy pads 238 of the present disclosure may reduce the formation of cracks in a gap fill material that is applied around the upper semiconductor die, and improves the bonding yield and enhances the reliability of composite dies 900 including a bonded assembly of semiconductor dies that are bonded through metal-to-metal bonding or hybrid bonding.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph or in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor structure, comprising:
forming a first molding compound around a first semiconductor die such that a top surface of the first molding compound is coplanar with a top dielectric surface of the first semiconductor die;
forming a combination of at least one bonding-level dielectric layer, first bonding pads, and dummy pads over the first semiconductor die and the first molding compound, wherein each of the first bonding pads is formed directly on a respective conductive structure within the first semiconductor die; and
attaching a second semiconductor die including second bonding pads therein to the first semiconductor die by performing a bonding process that bonds the second bonding pads to the first bonding pads by metal-to-metal bonding such that a first subset of the dummy pads has an areal overlap in a plan view with the second semiconductor die.

2. The method of claim 1, wherein:
the second semiconductor die comprises an edge seal ring structure that extends continuously along all sidewalls of the second semiconductor die; and
the method comprises positioning the second semiconductor die over the first semiconductor die during the bonding process such that at least one dummy pad within the first subset of the dummy pads overlaps with the edge seal ring structure in the plan view.

3. The method of claim 1, wherein:
the second semiconductor die comprises an edge seal ring structure that extends continuously along all sidewalls of the second semiconductor die; and
the method comprises positioning the second semiconductor die over the first semiconductor die during the bonding process such that at least one dummy pad within the first subset of the dummy pads is at least partly within an area enclosed by the edge seal ring structure in the plan view.

4. The method of claim 1, wherein:
the second semiconductor die comprises an edge seal ring structure that extends continuously along all sidewalls of the second semiconductor die; and
the method comprises positioning the second semiconductor die over the first semiconductor die during the bonding process such that at least one dummy pad within the first subset of the dummy pads is located at least partly within a frame-shaped area located between an outer periphery of the edge seal ring structure and sidewalls of the second semiconductor die in the plan view.

5. The method of claim 1, wherein:
the dummy pads are formed by depositing and patterning a first fill material within a first subset of the at least one bonding-level dielectric layer; and
the first bonding pads are formed by depositing and patterning a second fill material within the at least one bonding-level dielectric layer such that each of the first bonding pads vertically extend from a bottommost surface of the at least one bonding-level dielectric layer to a topmost surface of the at least one bonding-level dielectric layer.

6. The method of claim 5, wherein:
the first fill material is deposited by a first deposition process and is planarized by a first planarization process to form the dummy pads; and
the second fill material is deposited by a second deposition process and is planarized by a second planarization process to form the first bonding pads, the second deposition process being different from the first deposition process.

7. The method of claim 5, further comprising:
depositing a second subset of the at least one bonding-level dielectric layer over the dummy pads; and
forming bonding-pad cavities through the second subset and through the first subset, wherein the first bonding pads are formed in the bonding-pad cavities.

8. A method of forming a semiconductor structure, comprising:
forming a first molding compound around a first semiconductor die such that a top surface of the first molding compound is coplanar with a top dielectric surface of the first semiconductor die;
forming dummy-pad cavities through a first subset of at least one bonding-level dielectric layer which is formed over the first molding compound;
forming dummy pads by depositing a first fill material in the dummy-pad cavities;
forming bonding-pad cavities through each layer of the at least one bonding-level dielectric layer;
forming first bonding pads by depositing a second fill material in the bonding-pad cavities, wherein each of the first bonding pads is formed directly on a respective conductive structure within the first semiconductor die, wherein the first bonding pads are formed prior to, or after, formation of the dummy pads; and
attaching a second semiconductor die including second bonding pads therein to the first semiconductor die by performing a bonding process that bonds the second bonding pads to the first bonding pads by metal-to-metal bonding.

9. The method of claim 8, wherein:
the dummy-pad cavities are formed with a first depth; and
the bonding-pad cavities are formed with a second depth that is greater than the first depth.

10. The method of claim 8, further comprising performing a first planarization process that removes excess portions of the first fill material from above a horizontal plane including a topmost surface of the first subset of at least one bonding-level dielectric layer.

11. The method of claim 10, wherein the bonding-pad cavities are formed after performing the first planarization process.

12. The method of claim 10, further comprising performing a second planarization process that removes excess portions of the second fill material from above a horizontal plane including a topmost surface of the at least one bonding-level dielectric layer, wherein the first bonding pads comprise remaining portions of the second fill material after the second planarization process.

13. The method of claim 8, wherein:
the first fill material has a first material composition, and is deposited by performing a first deposition process; and
the second fill material has a second material composition that is different from the first material composition, and is deposited by performing a second deposition process that is different from the first deposition process.

14. The method of claim 8, wherein:
the first subset of the at least one bonding-level dielectric layer is less than an entirety of the at least one bonding-level dielectric layer; and
the method comprises depositing a second subset of the at least one bonding-level dielectric layer over the first subset of the at least one bonding-level dielectric layer.

15. A semiconductor structure comprising:
a molding compound laterally surrounding a first semiconductor die and having a top surface that is coplanar with a top dielectric surface of the first semiconductor die;
at least one bonding-level dielectric layer having formed therein first bonding pads and dummy pads and located over the first semiconductor die and the molding compound, wherein each of the first bonding pads electrically connected to a respective conductive structure within the first semiconductor die; and
a second semiconductor die including second bonding pads that are bonded to the first bonding pads by metal-to-metal bonding, wherein a first subset of the dummy pads has an areal overlap in a plan view with the second semiconductor die.

16. The semiconductor structure of claim 15, wherein:
the second semiconductor die comprises an edge seal ring structure that extends continuously along all sidewalls of the second semiconductor die; and
at least one dummy pad within the first subset of the dummy pads overlaps with the edge seal ring structure in the plan view.

17. The semiconductor structure of claim 15, wherein one of the dummy pads has a different material composition than the first bonding pads.

18. The semiconductor structure of claim 15, wherein one of the dummy pads has a top surface that is vertically offset from a horizontal plane including top surfaces of the first bonding pads.

19. The semiconductor structure of claim 15, wherein one of the dummy pads has a bottom surface that is vertically offset from a first horizontal plane including bottom surfaces of the first bonding pads.

20. The semiconductor structure of claim 19, wherein an additional one of the dummy pads comprises a via portion that extends to the first horizontal plane and contacts an additional conductive structure within the first semiconductor die, and is spaced apart from any conductive structure located on, or within, the second semiconductor die.
